(19) United States
(12) Patent Application Publication
(10) Pub. No.: US 2026/0223314 A1
(43) Pub. Date: Jul. 30, 2026

(54) HIGH-DENSITY SWITCHING EMBODIMENTS FOR SCALE-OUT FABRICS

(71) Applicant: DELL PRODUCTS L.P., Round Rock, TX (US)

(72) Inventors: Claudio DESANTI, Santa Cruz, CA (US); Joseph LaSalle WHITE, San Jose, CA (US); Macen Kanemi SHINSATO, Georgetown, TX (US)

(73) Assignee: DELL PRODUCTS L.P., Round Rock, TX (US)

(21) Appl. No.: 19/189,240

(22) Filed: Apr. 24, 2025

Related U.S. Application Data
(63) Continuation-in-part of application No. 19/041,990, filed on Jan. 30, 2025.
(63) Continuation-in-part of application No. 19/189,227, filed on Apr. 24, 2025.

(51) Int. Cl. H05K 7/14; H01R 13/703

(52) U.S. Cl. CPC H05K 7/1492; H01R 13/703

(57) ABSTRACT

Presented herein are high-density switching embodiments for networks (e.g., scale-out fabrics) in data centers, particularly for machine learning (ML) and artificial intelligence (AI) applications. Embodiments support improved topologies to optimize network efficiency, reduce latency, and enhance scalability. The present patent document details various configurations, including rail-optimized topologies, interconnect cable systems, and rack designs that support liquid cooling and high-density switching. At least some of the embodiments employ copper cabling for cost-effective interconnections. Embodiments provide efficient data handling and communication in high-computation environments while achieving better performance and reducing infrastructure costs, among other benefits.

### CROSS-REFERENCE TO RELATED APPLICATIONS

This patent application is a continuation-in-part application of and claims priority benefit under 35 USC § 120 to co-pending and commonly-owned U.S. patent application Ser. No. 19/041,990, filed on 30 Jan. 2025, entitled “TOPOLOGIES FOR SCALE-OUT FABRICS,” and listing Claudio DESANTI and Joseph L. WHITE as inventors (Docket No. DC-141264.01 (20110-2788)), which patent document is incorporated by reference herein in its entirety and for all purposes.

This patent application is a continuation-in-part application of and claims priority benefit under 35 USC § 120 to co-pending and commonly-owned U.S. patent application Ser. No. 19/189,227, filed on 24 Apr. 2025, entitled “DESIGN EMBODIMENTS TO SCALE AN IN-RACK SCALE-UP FABRIC,” and listing Claudio DESANTI, Joseph L. WHITE, and Macen SHINSATO as inventors (Docket No. DC-142162.01 (20110-2792)), which patent document is incorporated by reference herein in its entirety and for all purposes.

### BACKGROUND

### A. Technical Field

The present disclosure relates generally to information handling systems. M ore particularly, the present disclosure relates to data centers and/or computing centers.

### B. Background

The subject matter discussed in the background section shall not be assumed to be prior art merely as a result of its mention in this background section. Similarly, a problem mentioned in the background section or associated with the subject matter of the background section should not be assumed to have been previously recognized in the prior art. The subject matter in the background section merely represents different approaches, which in and of themselves may also be inventions.

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use, such as financial transaction processing, airline reservations, enterprise data storage, or global communications. In addition, information handling systems may include a variety of hardware and software components that may be configured to process, store, and communicate information and may include one or more computer systems, data storage systems, and networking systems.

The ever-increasing development and use of machine learning and artificial intelligence (ML/AI) applications has created a dramatic increase in demand for computing resources and processing resources. Graphics processing units, with their specially designed architectures, are particularly well suited for using in ML/AI applications—both training and inferencing. With increasingly complex ML/AI models, more and more processing systems are needed.

Thus, the exponentially growing complexity of ML/AI models and their ever-growing voracious need for data have created needs for data centers with vast numbers of processing units and supporting infrastructure. The supporting infrastructure, including information handling systems, such as network switches, and cabling, have also become more complex and more closely tied to the ML/AI deployment. For example, in addition to needing large numbers of complex processing information handling systems, aspects such as physical placement, type of cabling, and network topology should be considered. Because of the staggering number of computation operations that are involved in most modern M L/AI applications, even a small fraction of a second delay in processing aggregates into a significant amount.

Accordingly, it is highly desirable to find new, more efficient ways to structure data centers/computing centers to achieve high density, high-computation environments.

### BRIEF DESCRIPTION OF THE DRAWINGS

References will be made to embodiments of the disclosure, examples of which may be illustrated in the accompanying figures. These figures are intended to be illustrative, not limiting. Although the accompanying disclosure is generally described in the context of these embodiments, it should be understood that it is not intended to limit the scope of the disclosure to these particular embodiments. Items in the figures may not be to scale.

FIG. 1 (“FIG. 1”) depicts an example NVL72 system from NVIDIA Corporation, according to embodiments of the present disclosure.

FIG. 2 depicts a simplified view of a typical GPU, such as an NVIDIA H100 by NVIDIA Corporation.

FIG. 3A depicts a compute sled containing four (4) Blackwell GPUs and two (2) Grace processors.

FIG. 3B depicts a different implementation of a compute sled containing four (4) Blackwell GPUs and two (2) Grace processors.

FIG. 4A depicts an example top-of-rack (TOR)-wired Clos topology.

FIG. 4B depicts an example rail topology.

FIG. 4C depicts an example rail-optimized topology, according to embodiments of the present disclosure.

FIG. 5 depicts an NVL72 AI fabric model.

FIG. 6 shows an NVIDIA topology for a 9216 GPUs cluster, where there are four (4) rails.

FIG. 7 shows a possible NVIDIA rack structure for 9216 GPUs, with eight (8) railpods supporting four (4) rails.

FIG. 8 depicts an example of a 9216 GPUs cluster, according to embodiments of the present disclosure.

FIG. 9 depicts an example implementation of a rack design for the topology depicted in FIG. 10, according to embodiments of the present disclosure.

FIG. 10 depicts a topology that supports 9216 GPUs, according to embodiments of the present disclosure.

FIG. 11 depicts another embodiment topology, according to embodiments of the present disclosure.

FIG. 12 depicts the use of copper cables between spines and superspines, according to embodiments of the present disclosure.

FIG. 13 depicts an updated topology, according to embodiments of the present disclosure.

FIG. 14 depicts an example rack design for a topology depicted in FIG. 13, according to embodiments of the present disclosure.

FIG. 15 depicts two ways (1500A and 1500B) to use double density copper cables between spines and superspine switches to support a topology depicted in FIG. 13, according to embodiments of the present disclosure.

FIG. 16 depicts an example topology with oversubscription, according to embodiments of the present disclosure.

FIG. 17 depicts a possible racking solution for the spine and superspine switches, according to embodiments of the present disclosure.

FIG. 18 depicts an example rack implementation, according to embodiments of the present disclosure.

FIG. 19 comprises a table comparing two topologies, according to embodiments of the present disclosure.

FIG. 20 depicts a cluster of GPUs that utilize network rails, according to embodiments of the present disclosure.

FIG. 21 illustrates a mismatch between the number of ports of a set of GPUs and the number of ports of switches, according to embodiments of the present disclosure.

FIG. 22 depicts a methodology for configuring a topology, according to embodiments of the present disclosure.

FIG. 23 depicts a scale-out fabric topology for a 9216 GPUs cluster with 64-port switches, according to embodiments of the present disclosure.

FIG. 24 depicts a two-rack set of spine switches and superspine switches, according to embodiments of the present disclosure.

FIG. 25 depicts a rack layout for a 9216 GPUs cluster using 64-port switches, according to embodiments of the present disclosure.

FIG. 26 shows two possible options routing the DAC cables, according to embodiments of the present disclosure.

FIG. 27 depicts a scale-out fabric topology for a 9216 GPUs cluster, according to embodiments of the present disclosure.

FIG. 28 depicts a four-rack set of spine-superspine switches, according to embodiments of the present disclosure.

FIG. 29 depicts a rack layout using four set of 4-rack spine-superspine switches for a 9216 GPUs cluster using 128-port switches, according to embodiments of the present disclosure.

FIG. 30 depicts cable routing for 128-port switches spine-superspines racks, according to embodiments of the present disclosure.

FIG. 31 depicts an NVL72 system.

FIG. 32 shows a top view of a modified rack, according to embodiments of the present disclosure.

FIG. 33 graphically illustrates the structure of two switches, according to embodiments of the present disclosure.

FIG. 34 depicts two types of switches installed in a rack and interconnected by an interconnect cable system, according to embodiments of the present disclosure.

FIG. 35 depicts a view of a rack switch design for 36 leaf switches (which may be spine switches in the topology of FIG. 23) and 32 spine switches (which may be used as superspine switches in the topology of FIG. 23), according to embodiments of the present disclosure.

FIG. 36 depicts a simplified rack layout for a topology like the one depicted in FIG. 23, according to embodiments of the present disclosure.

FIG. 37 depicts a rack switch with 32 leaf switches and 16 spine switches, according to embodiments of the present disclosure.

FIG. 38 depicts a rack embodiment that includes processing unit modules in addition to switching modules, according to embodiments of the present disclosure.

FIG. 39 depicts an alternative configuration for a rack-scale switch system, according to embodiments of the present disclosure.

FIG. 40 depicts a rack configuration of FIG. 39 with processor modules included, according to embodiments of the present disclosure.

FIG. 41 depicts an example methodology for configuring/using a rack system, according to embodiments of the present disclosure.

FIG. 42 depicts a simplified block diagram of an information handling system, according to embodiments of the present disclosure.

FIG. 43 depicts an alternative block diagram of an information handling system, according to embodiments of the present disclosure.

### DETAILED DESCRIPTION OF EMBODIMENTS

In the following description, for purposes of explanation, specific details are set forth in order to provide an understanding of the disclosure. It will be apparent, however, to one skilled in the art that the disclosure can be practiced without these details. Furthermore, one skilled in the art will recognize that embodiments of the present disclosure, described below, may be implemented in a variety of ways, such as a process, an apparatus, a system/device, or a method on a tangible computer-readable medium.

Components, or modules, shown in diagrams are illustrative of exemplary embodiments of the disclosure and are meant to avoid obscuring the disclosure. It shall be understood that throughout this discussion that components may be described as separate functional units, which may comprise sub-units, but those skilled in the art will recognize that various components, or portions thereof, may be divided into separate components or may be integrated together, including, for example, being in a single system or component. It should be noted that functions or operations discussed herein may be implemented as components. Components may be implemented in software, hardware, or a combination thereof.

Furthermore, connections between components or systems within the figures are not intended to be limited to direct connections. Rather, data between these components may be modified, re-formatted, or otherwise changed by intermediary components. Also, additional or fewer connections may be used. It shall also be noted that the terms “coupled,” “connected,” “communicatively coupled,” “interfacing,” “interface,” or any of their derivatives shall be understood to include direct connections, indirect connections through one or more intermediary devices, and wireless connections. It shall also be noted that any communication, such as a signal, response, reply, acknowledgement, message, query, etc., may comprise one or more exchanges of information.

Reference in the specification to “one or more embodiments,” “preferred embodiment,” “an embodiment,” “embodiments,” or the like means that a particular feature, structure, characteristic, or function described in connection with the embodiment is included in at least one embodiment of the disclosure and may be in more than one embodiment. Also, the appearances of the above-noted phrases in various places in the specification are not necessarily all referring to the same embodiment or embodiments.

The use of certain terms in various places in the specification is for illustration and should not be construed as limiting. The terms “include,” “including,” “comprise,” “comprising,” and any of their variants shall be understood to be open terms, and any examples or lists of items are provided by way of illustration and shall not be used to limit the scope of this disclosure.

A service, function, or resource is not limited to a single service, function, or resource; usage of these terms may refer to a grouping of related services, functions, or resources, which may be distributed or aggregated. The use of memory, database, information base, data store, tables, hardware, cache, and the like may be used herein to refer to system component or components into which information may be entered or otherwise recorded. The terms “data,” “information,” along with similar terms, may be replaced by other terminologies referring to a group of one or more bits, and may be used interchangeably. The terms “packet” or “frame” shall be understood to mean a group of one or more bits. The term “frame” shall not be interpreted as limiting embodiments of the present invention to Layer 2 networks; and, the term “packet” shall not be interpreted as limiting embodiments of the present invention to Layer 3 networks. The terms “packet,” “frame,” “data,” or “data traffic” may be replaced by other terminologies referring to a group of bits, such as “datagram” or “cell.” The words “optimal,” “optimize,” “optimization,” and the like refer to an improvement of an outcome or a process and do not require that the specified outcome or process has achieved an “optimal” or peak state.

It shall be noted that: (1) certain steps may optionally be performed; (2) steps may not be limited to the specific order set forth herein; (3) certain steps may be performed in different orders; and (4) certain steps may be done concurrently.

Any headings used herein are for organizational purposes only and shall not be used to limit the scope of the description or the claims. Each reference/document mentioned in this patent document is incorporated by reference herein in its entirety.

Any embodiment or embodiments described herein are not necessarily limited strictly to the features expressly described for that specific embodiment and may also (or alternatively) include properties and/or features (e.g., ingredients, components, members, elements, parts, regions, property, and/or functions) described for one or more separate embodiments. Accordingly, the various features of a given embodiment or embodiments may be combined with and/or incorporated into another embodiment or embodiments. Disclosure of certain features relative to a specific embodiment or embodiments should not be construed as limiting application or inclusion of said features to the specific embodiment or embodiments. Rather, it will be appreciated that other embodiments may also include such features.

It shall be noted that any experiments and results provided herein are provided by way of illustration and were performed under specific conditions using a specific embodiment or embodiments; accordingly, neither these experiments nor their results shall be used to limit the scope of the disclosure of the current patent document.

It shall also be noted that although embodiments described herein may be within the context of ML/AI applications or NVL72 systems, aspects of the present disclosure are not so limited. Accordingly, the aspects of the present disclosure may be applied or adapted for use with other equipment and in other contexts.

### A. General Introduction

Multiple entities, particularly those wanting to develop and/or deploy ML/AI applications, desire high density rack-scale graphics processing unit (GPU) solutions. One such system is the NVL72 system from NVIDIA Corporation, a multinational corporation headquartered in Santa Clara, California.

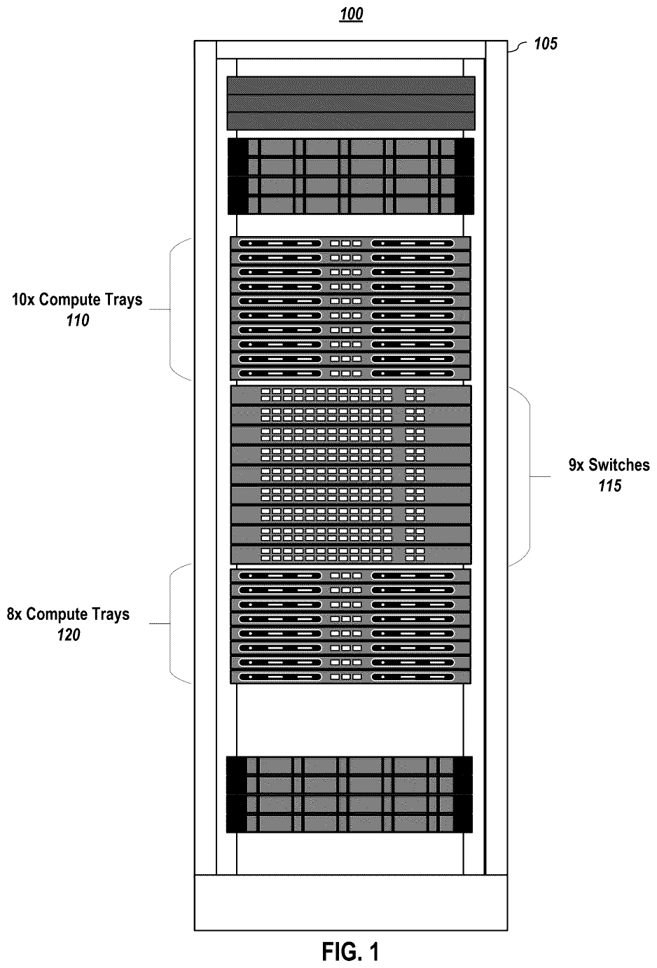

FIG. 1 depicts an example NVL72 system 100. The NVL72 system typically comprises eighteen (18) compute sleds (or trays) 110 and 120 and nine (9) switches 115 for data traffic processing-all housed within a rack 105. The system may comprise additional elements, such as power supplies, cooling system(s), redundancy system(s), additional processing information handling system(s), among other elements common to a network or data center rack.

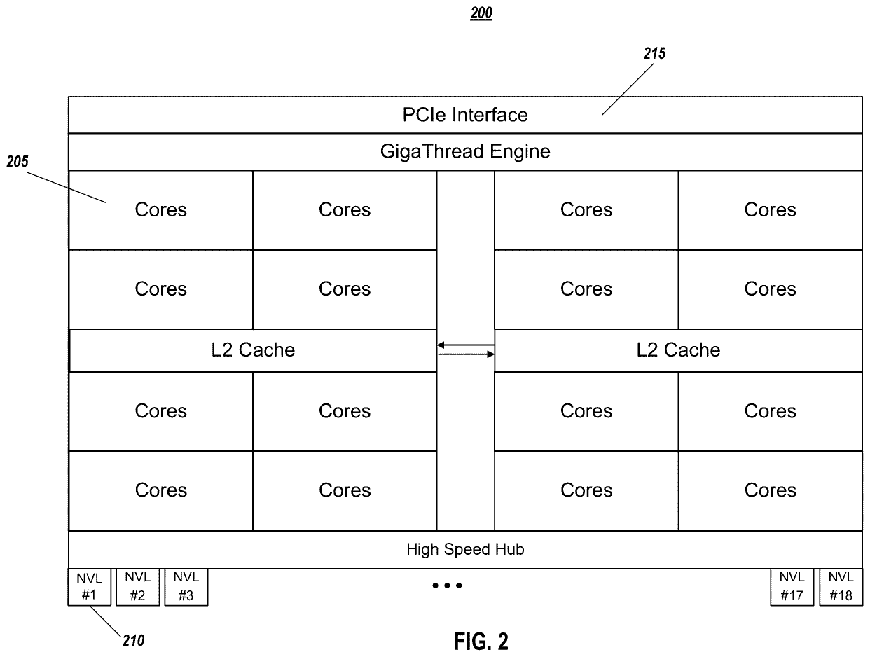

FIG. 2 depicts a simplified view of a typical GPU, such as an NVIDIA H100 by NVIDIA Corporation. The GPU depicted in FIG. 2 represents a high-performance accelerator designed primarily for artificial intelligence (AI), machine learning (ML), and high-performance computing (HPC) workloads. Such GPUs feature a significant performance boost in enhanced computational power, scalability, and energy efficiency. Some key features of the GPU 200 include:
tensor cores 205 optimized for AI workloads, enabling faster training and inference for deep learning models;
NVLinks with a high-speed hub 210 and PCIe Gen5 215 for high-bandwidth, low-latency communication, enabling efficient scaling across multiple GPUs;
a hopper architecture, which introduces support for advanced operations like sparsity, further accelerating AI computations; and
other supporting elements, such as L2 cache.

The GPU supports increased memory bandwidth and large memory capacity, allowing it to handle massive datasets and complex models. The PCIe interface(s) 215 provide interfaces for a “scale-out” fabric to connect to other systems and the NVLinks 210 provide interfaces for “scale-up” connectivity within the NVL72 unit.

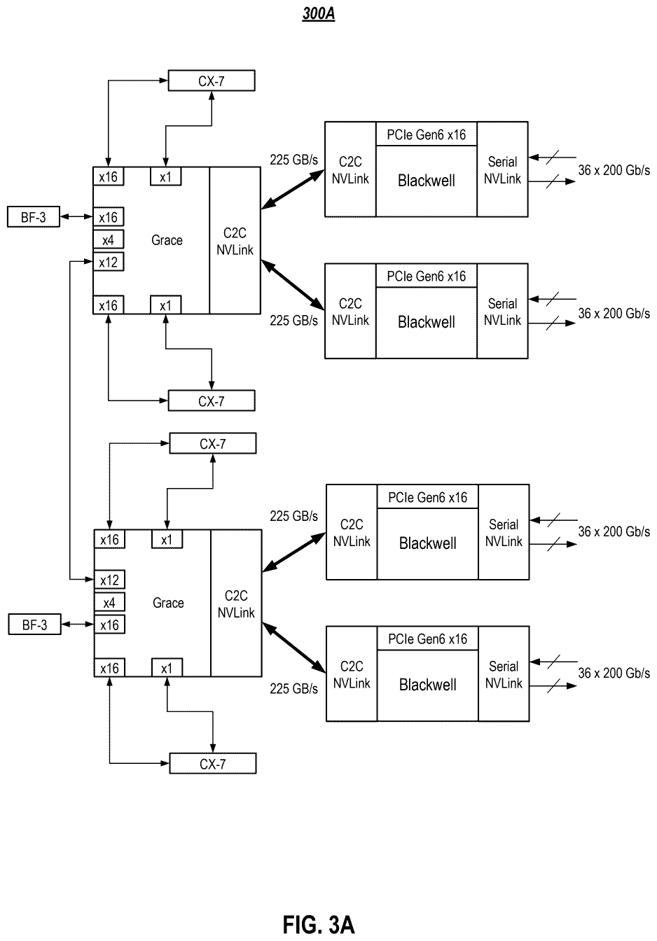

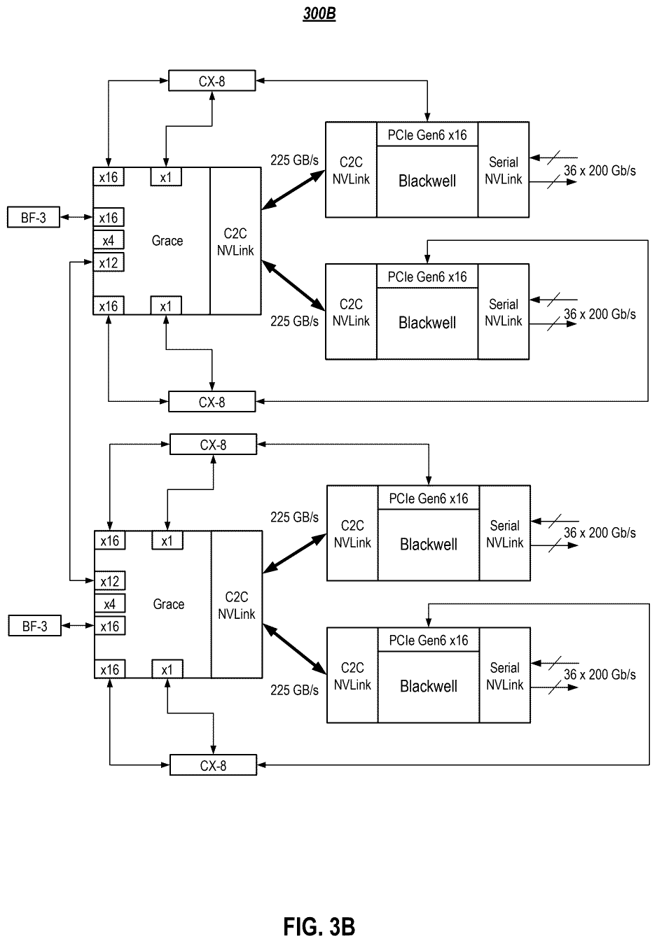

Each compute tray typically contains 4 Blackwell GPUs and two Grace processors, as shown in FIG. 3A and FIG. 3B. Each Grace processor typically supports a BlueField-3 (BF3) data processing unit (D PU) to connect to a front-end fabric and two network interface cards (NICs), each coupled with one GPU, to connect to a scale-out fabric. The NIC used currently is a 400 Gb/s (gigabit per second) CX-7 NIC, as shown in FIG. 3A; in the future, the CX-7 NICs will likely be replaced by 800 Gb/s CX-8 NICs that will be also directly connected to the Blackwell GPUs, as shown in FIG. 3B. Each Blackwell GPU is also directly connected to an NVLink-based scale-up fabric for high-bandwidth parameter exchanges among GPUs within the rack.

For the scale-out fabric topology, there are at least a few potential options.

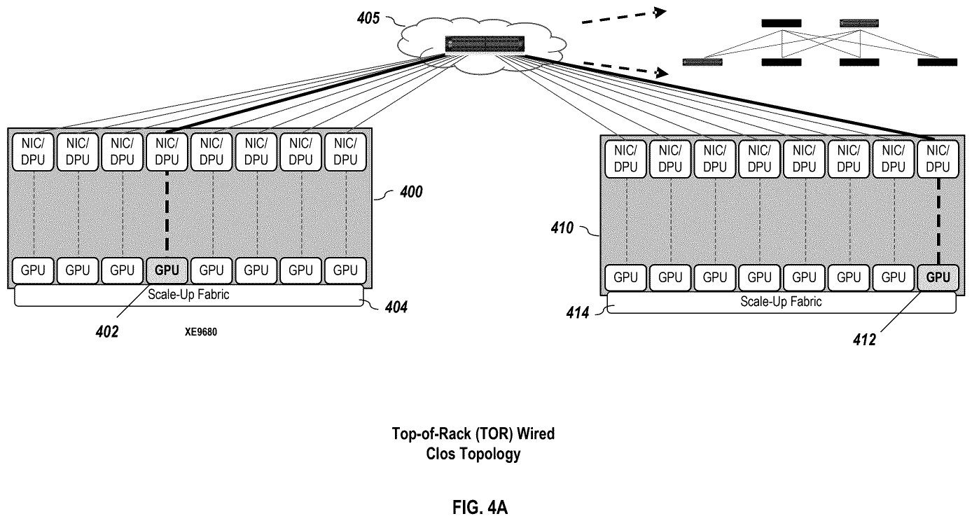

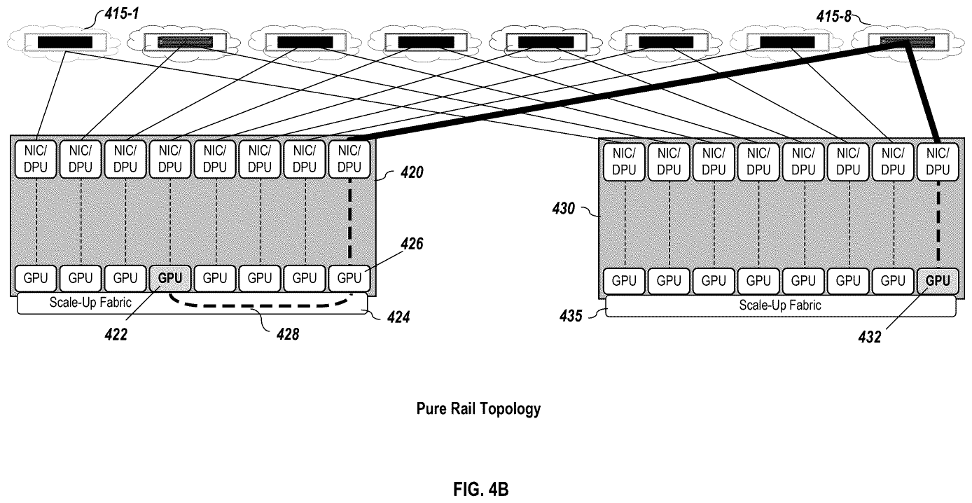

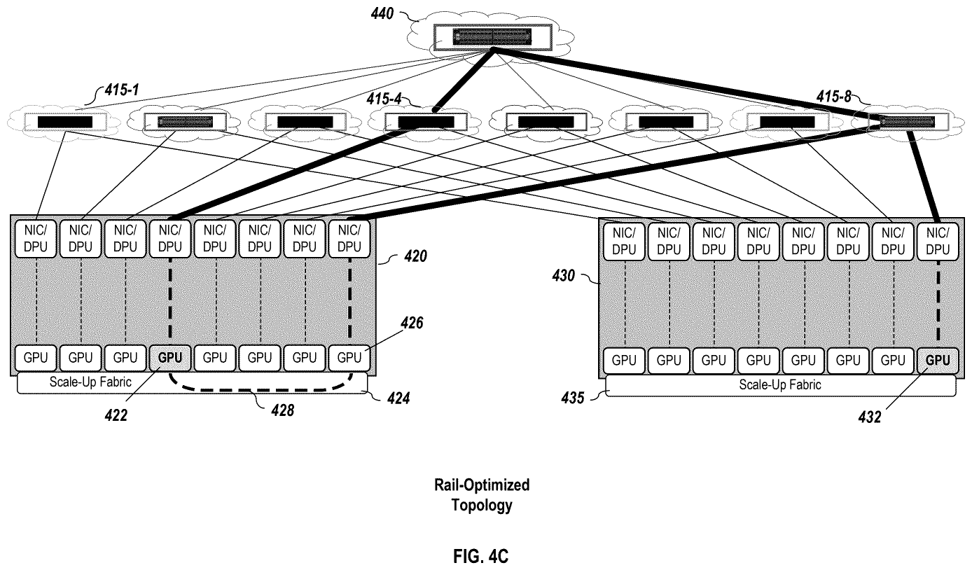

FIG. 4A depicts a top-of-rack (TOR)-wired Clos topology. This topology allows direct scale-out fabric communication between any GPU pairs. For example, a GPU 402 in compute system 400 may communicate with a GPU 412 in another compute system 410 via the fabric 405. Note that the compute system's scale-up fabric 404/414 is not involved in the scale-out fabric communication.

FIG. 4B depicts a rail topology. This topology comprises independent networks (or “rails”)—in the depicted example, there are eight (8) rails 415-1 through 415-8. For a pure rail topology, direct scale-out fabric communication is between GPUs belonging to the same rail. For example, a GPU 426 in compute system 420 may communicate with a GPU 432 in another compute system 430 via the rail network 415-8. For a GPU of one compute system to communicate with a GPU of another compute system that are not members of the same rail network, the scale-up network is employed. For example, for GPU 422 in compute system 420 to communicate with GPU 432 in the compute system 430, GPU 422 communicates via the scale-up fabric 424 with its peer GPU 426, which in turn communicates with GPU 432 via the rail network 415-8.

FIG. 4C depicts a rail-optimized topology, according to embodiments of the present disclosure. This topology comprises independent networks (or “rails”), similar to that of FIG. 4B, but the rails are interconnected by one or more upper tiers 440. This topology is similar to that of FIG. 4B, allowing the same data pathways as in FIG. 4B. However, in addition to the pathways of FIG. 4B, FIG. 4C also includes a direct scale-out fabric communication pathway between GPU s belonging to different rails when on different compute systems. For example, GPU 426 on compute system 420 has the same pathway via the scale-up fabric and scale-out fabric to communicate with GPU 432 on compute system 430 as depicted in FIG. 4B, but it also can communicate with GPU 432 via the scale-out fabric via rail 415-4, upper layer 440, and rail 415-8.

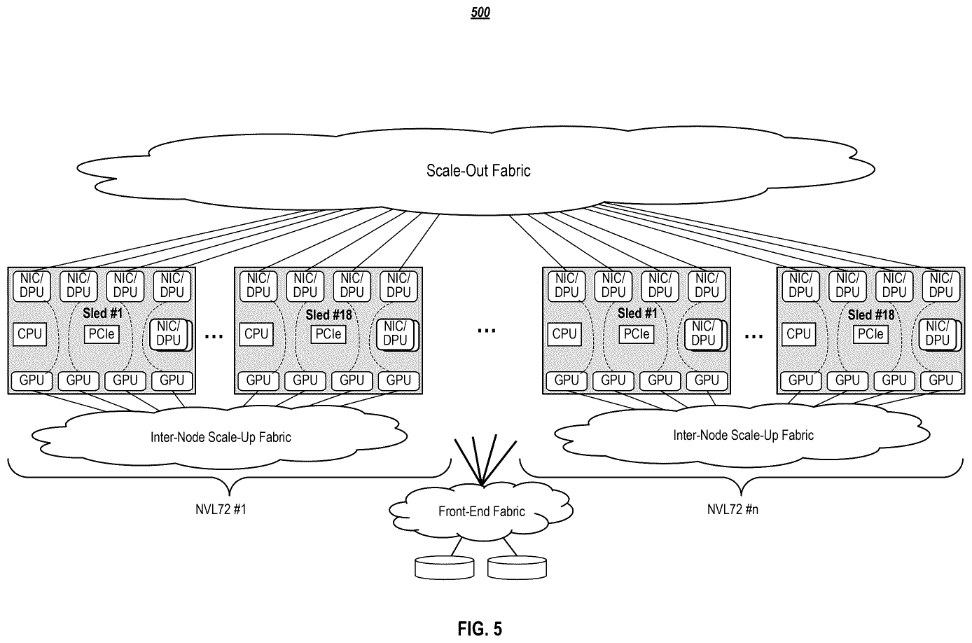

Typically, each Blackwell GPU is also directly connected to an NVLink-based scale-up fabric for high-bandwidth parameter exchanges among GPUs within the rack. A corresponding NVL72 AI fabric model 500 is shown in FIG. 5.

It should be noted that there is a benefit to communicating via the scale-up fabric. The GPU trays comprise PXN (PCI×NVLink), which is an NCCL feature that enables a GPU to communicate with a NIC on the node through NVLink and then PCI. NCCL, which stands for NVIDIA Collective Communications Library, is a high-performance library developed by NVIDIA that provides optimized implementations of collective communication operations for distributed deep learning, multi-GPU, and multi-node applications. It is designed to help developers and researchers efficiently scale their workloads across multiple GPUs, compute systems, or nodes in high-performance computing (HPC) and machine learning environments.

NCCL enables fast and efficient communication between GPUs, leveraging the high bandwidth and low latency of NVIDIA's interconnect technologies like NVLink and PCIe. It simplifies the process of parallelizing machine learning tasks by handling the complex communication patterns required for distributed training, such as data parallelism. NCCL also provides optimized implementations of common collective communication operations used in Al/ML applications, such as: (1) AllReduce: Combines data across all participating devices and shares the result (typically used for aggregating gradients in distributed deep learning); (2) AllGather: Gathers data from all devices and concatenates it across all participating devices; (3) Broadcast: Distributes data from one device to all other devices; (4) Reduce: Combines data from multiple devices into one (e.g., summing gradients across devices); and (5) ReduceScatter: Splits and reduces data across multiple devices.

NCCL can also efficiently manage communication between GPUs within a single node or across multiple nodes in a distributed system. It supports multi-GPU configurations on a single machine, as well as cross-node communication, which is helpful for scaling large deep learning models. NCCL is configured to take full advantage of NVIDIA's hardware features, including NVLink, NVSwitch, and InfiniBand for fast inter-GPU and inter-node communication. Additionally, the library supports efficient peer-to-peer communication between GPUs, which reduces the overhead of using the CPU or system memory as an intermediary. This is particularly beneficial for high-throughput operations like deep learning model training. Finally, NCCL includes features like dynamic load balancing, which helps ensure efficient communication.

Concerning use of the scale-up fabric, with PXN, instead of preparing a buffer on its local memory for the local NIC to send, the GPU prepares a buffer on an intermediate GPU, writing to it through NVLink. In one or more embodiments, PXN leverages NVIDIA NVSwitch connectivity between GPUs to first move data on a GPU on the same rail as the destination, then send it to the destination without crossing rails. With PXN, all GPUs on a given node may move their data onto a single GPU for a given destination. This allows aggregating messages, enabling the remote GPU to send all messages as one as soon as they are all ready.

Given the configuration of a typical NVIDIA system and the rail-optimized configuration of FIG. 4C, several benefits may be achieved. A GPU may leverage two different communication interfaces: a scale-up interface and a scale-out interface. The scale-up interface has a bandwidth approximately an order of magnitude higher than the scale-out interface. To set up a collective operation, in one or more embodiments, a GPU may determine which interface to using the following methodology:

```
If(a path through its Scale-up interface is available)
  then {use the Scale-up interface}
else if(a path through its Scale-out interface is available)
  then {use the Scale-out interface}
else {fail}.
```

Selecting a path through the scale-out interface is possible in a rail-optimized/rail-improved topology, because network rails are interconnected (e.g., see FIG. 4C). That is, the NCCL continues to operate in case of a link failure. In contrast, selecting a path through the scale-out interface is not possible in a pure rail topology (e.g., see FIG. 4B), because network rails are isolated. In such a case, the NCCL will hang or stall in case of a link failure.

Thus, in one or more embodiments, a scale-out fabric that is configured in a rail-optimized topology is best, because both scale-out and scale-up fabrics are used by GPUs to exchange parameters, and the high bandwidth scale-up fabric is the preferred way to cross rails within a rack.

The NIC (e.g., a CX-7 or CX-8 NIC) used for scale-out fabric connectivity may be available in two variants, InfiniBand and Ethernet. For InfiniBand connectivity, the currently available 400 Gb/s switch from NVIDIA is the QM 9700, having radix 64 (i.e., a total of 64 ports). Connecting the 72 scale-out ports in the NVL72 domain to a 64-port switch is an issue with multiple solution approaches. NVIDIA proposed a rail solution based on four rails, supporting a cluster of up to 18K GPUs, as shown in Table 1.

TABLE 1
NVIDIA Scale-out fabric Solution

| | Cluster Size | |
|---|---|---|
| | Max cluster size ≤ | 1152 GPUs ≤ Max cluster |
| | 576 GPUs | size ≤ 18432 GPUs |
| Scaling | Scale by adding NVL72 | Scale by adding 1152 GPUs |
| | racks | Pods |
| Fabric | 8 Leaves, 6 Spines per | 16 Leaves, 9 Spines per |
| topology | rail No SuperSpines | rail 9 SuperSpines group |

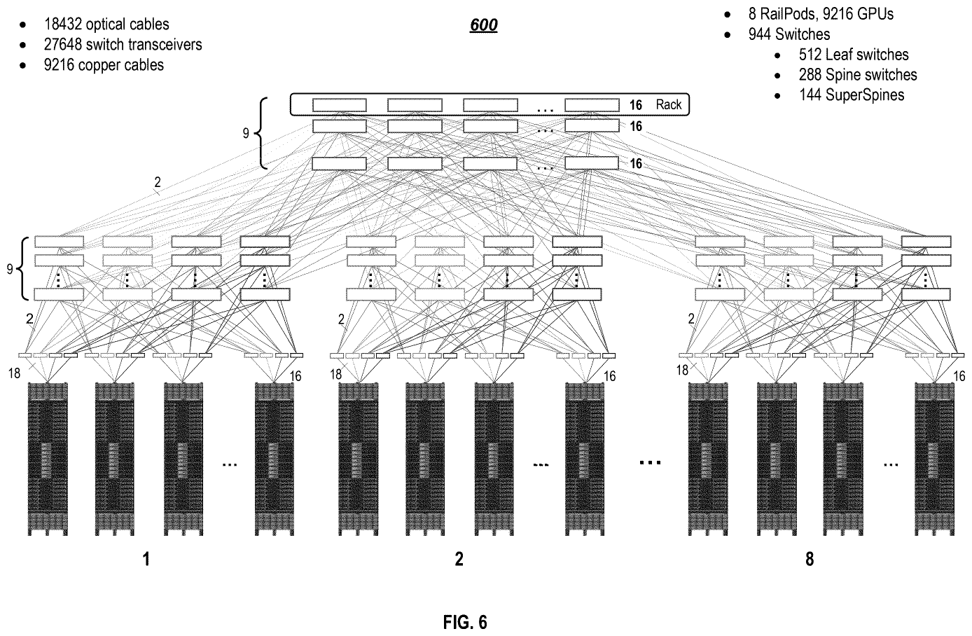

As an example, FIG. 6 shows the NVIDIA topology for a 9216 GPUs cluster, where there are four rails (see the color version of FIG. 6, which indicates the separate rails). The NVL72 racks are organized in railpods, each composed of 16 racks. Each NVL72 rack is connected with 18 links to four leaf switches, one per each rail. Per each railpod, there are four groups of spine switches, each composed of nine switches. Within a rail, each leaf switch is connected to the nine spine switches with two links. The leaf switches are sparsely populated, with just 36 out of 64 ports used. Per each railpod, each of the nine rows of four spine switches is connected with a corresponding row of 16 superspine switches. Both spine and superspine switches are fully populated.

The topology shown in FIG. 6 requires 944 switches (e.g., QM 9700 switches by NVIDIA) to be built. From a latency and traffic management point of view, it is not optimal, because all communications within a railpod require three hops (i.e., crossing a leaf, a spine, a leaf), and all communications within a rail require five hops (i.e., crossing a leaf, a spine, a superspine, a spine, a leaf).

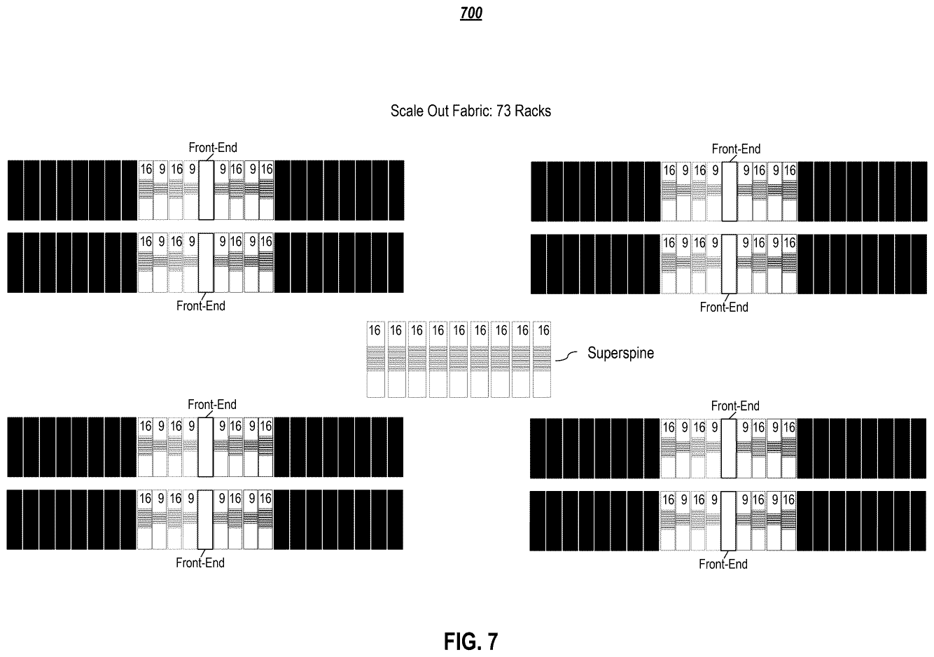

An advantage of this topology is that it allows co-locating spines and leaf switches of a rail in the same rack (or in two adjacent racks), enabling the use of cheaper copper-based DA C (direct attached copper) cables in place of more expensive optical cables and transceivers for the leaf to spine links, as shown in the possible rack design shown in FIG. 7. FIG. 7 shows a possible NVIDIA rack structure for 9216 GPUs, with eight (8) railpods supporting four (4) rails.

Using these configuration guidelines, the maximum scale fabric achievable with such a topology is a cluster of 18,432 GPUs. This cluster would be composed of 16 railpods (18432 GPUs) and 1888 switches (1024 leaf switches, 576 spine switches, and 288 superspine switches).

As noted above, this type of topology is not optimal because all communications within a railpod require three hops (i.e., crossing a leaf, a spine, a leaf) and all communications within a rail require five hops (i.e., crossing a leaf, a spine, a superspine, a spine, a leaf). The following section provide embodiments of better topologies, which may be referred to a rail-optimized or rail-improved topologies.

### B. Embodiments of Rail-Optimized/Rail-Improved Topologies

Embodiments of improved topologies for an NVL72 scale-up fabric may be achieved by having as many rails as allowed by the radix of the switch, in which radix refers to the number of ports or connections a router or switch can handle. For example, a scale-up fabric topology may comprise 36 rails for 64-port switches and 72 rails for 128-port switches. In one or more embodiments, the rails span the minimum number of tiers possible (i.e., restrict them to the first or second tier) and use the additional tier for the rail crossing function. If the last tier is used for the rail crossing function, it may be oversubscribed, because the preferred fabric to perform the rail crossing function is the scale-up fabric.

### 1. Improved Topology Embodiments Using Radix 64 Switches

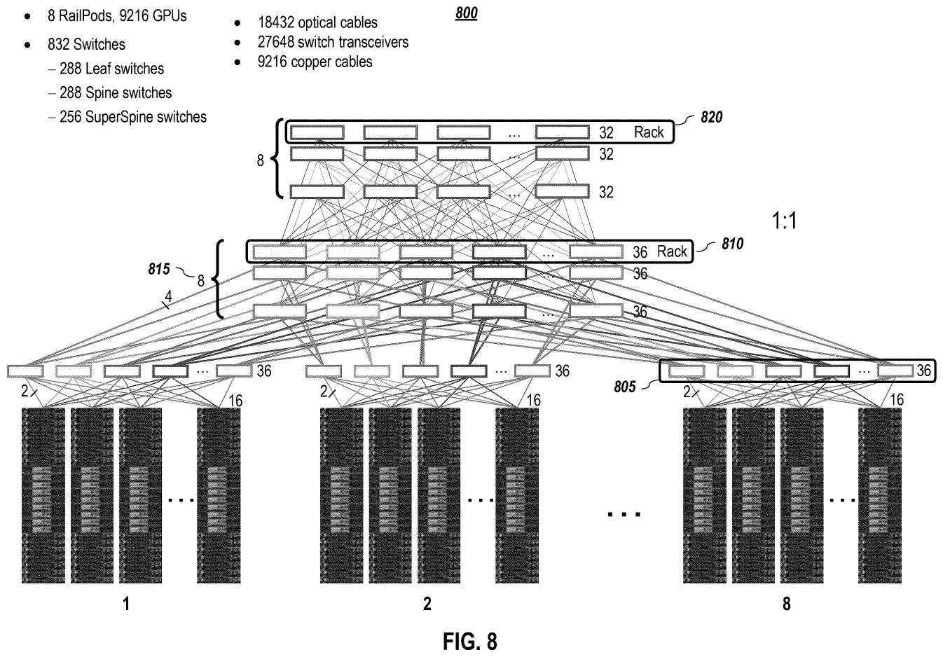

FIG. 8 depicts an example of a 9216 GPUs cluster, according to embodiments of the present disclosure. In one or more embodiments, the racks (which may be NVL72 racks) are organized in railpods, each comprising 16 racks—although different configurations and numbers may be used. The topology 800 was designed according to these principles. In the color version of the figures, the different colors indicate the 36 rails (e.g., a QM 9700 switch is a 64-port switch and may be used for each of the switches in the scale-up fabric, although other switches may be used). Each NVL72 rack is connected with two links to 36 leaf switches (e.g., set of 36 leaf switches 805), one per each rail. That is, each switch of a set of 36 leaf switches (e.g., set of 36 leaf switches 805) for a railpod (e.g., railpod 8) is a rail and connects to a corresponding rail in the spine layers, which also have 36 switches per row—one for each rail (see, e.g., set of spine switches 810). In the depicted example, there are 8 sets of 36 spine switches, which may be housed within a rack (e.g., set 810). However, stated differently when viewed per rail, the topology 800 includes 36 groups of spine switches, each comprising eight switches 815. Within a rail, each leaf switch may be connected to the eight spine switches with four links. In one or more embodiments, the leaf switches are fully populated, with all 64 ports used.

Also depicted in FIG. 8 are 8 rows of 32 superspine switches. In one or more embodiments, a set of 32 superspine switches (e.g., set 815) may be housed within a rack. Each of the eight rows of spine switches may be connected to a corresponding row of 32 superspine switches. In one or more embodiments, the spine switches are fully populated, with all 64 ports used, while the superspine switches are sparsely populated, with just 36 out of 64 ports used.

The topology shown in FIG. 8 uses 832 switches (e.g., 832 QM 9700 switches). From a latency and traffic management point of view, it is a better topology than the prior approaches because communications within a railpod involve one hop (i.e., crossing a leaf) and communications within a rail involve three hops (i.e., crossing a leaf, a spine, a leaf). Also note that the third tier is used for the rail crossing function (i.e., communicating across rails), and therefore it may be oversubscribed. Furthermore, this topology may scale larger (e.g., scaled to support 36864 GPUs).

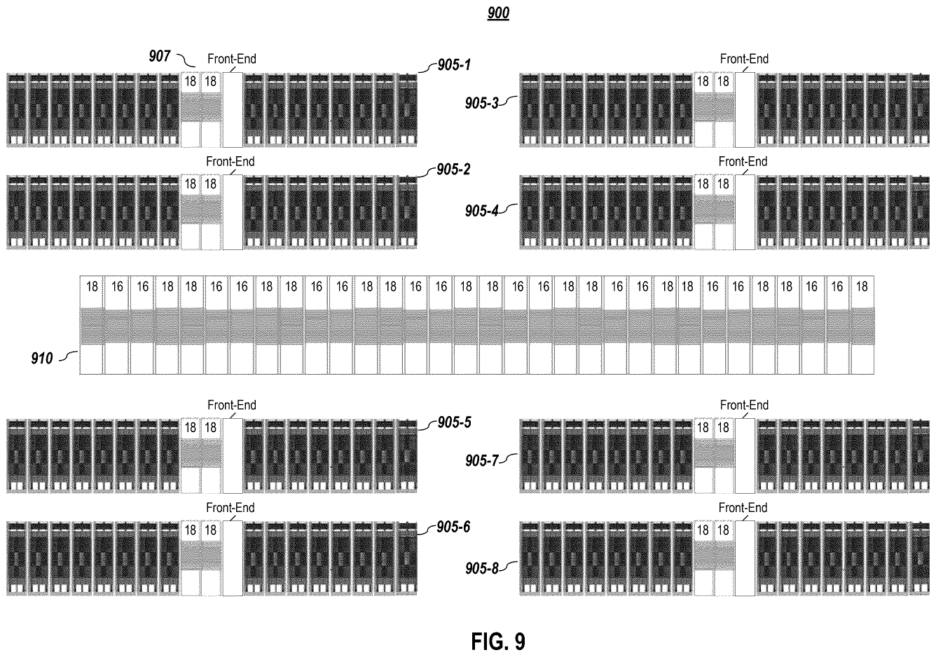

FIG. 9 depicts an example implementation of a rack design for the topology depicted in FIG. 8, according to embodiments of the present disclosure. The rack design comprises 8 railpods 905. Each railpod 905 comprises sixteen (16) NVL72 units and two racks that each house 18 leaf switches. The spines and superspines are represented by the central core 910. In one or more embodiments, as discussed in more detail below, the close proximity of spines and superspines may allow for the use of copper cabling, which is less expensive than optical cabling. For at least some of the connections between the NVL72 units and their leaf switches, optical cabling may be used. Similarly, optical cabling may be used between at least some of the leaf switches and for connections between the leaf switches and the spine switches.

In one or more embodiments, a front-end fabric is a fabric that connects to the remaining part of the data center and allows access to storage and to the GPU cluster itself. An example depiction of a front-end fabric is depicted in FIG. 5.

### 2. Improved Topology Embodiments Using Radix 128 Switches

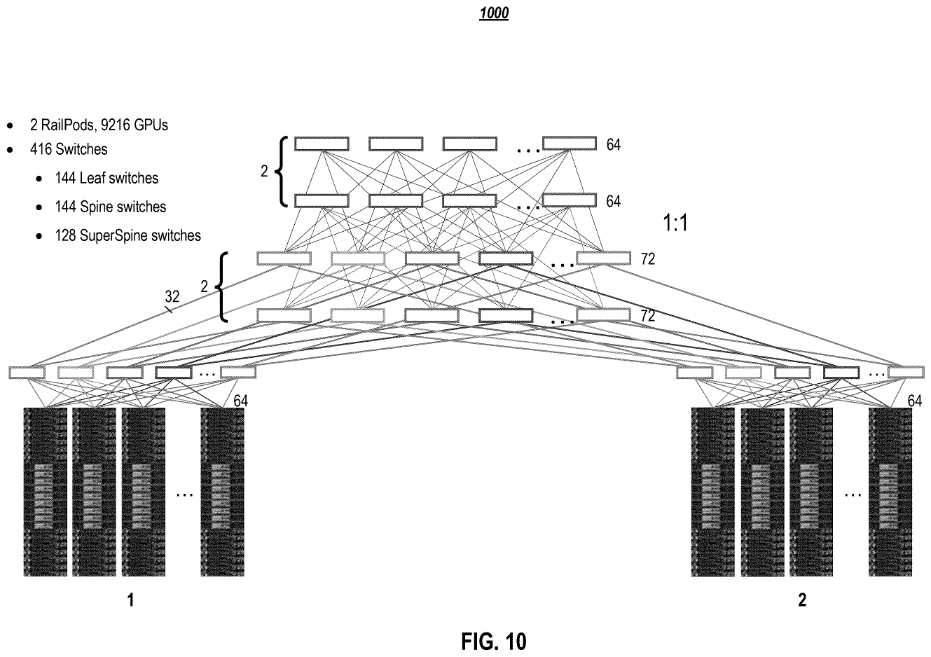

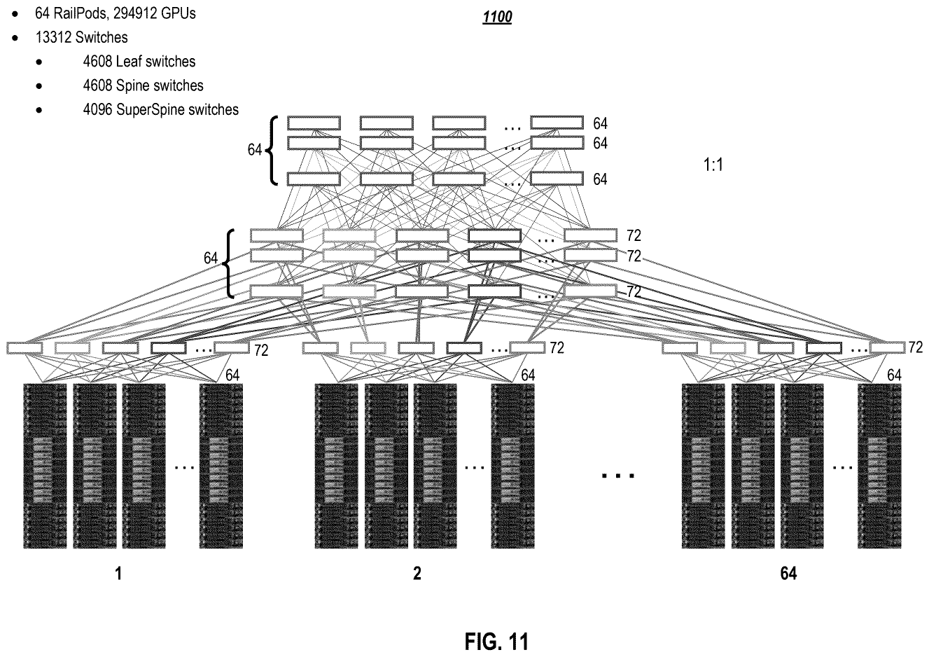

Note that the prior example embodiments involved using switches with 64 ports (i.e., radix of 64). FIG. 10 and FIG. 11 show improved topologies for switches with radix 128. In one or more embodiments, the switches may be Z9864 by Dell of Round Rock, Texas—although other radix 128 switches may be used.

FIG. 10 depicts a topology that supports 9216 GPUs, according to embodiments of the present disclosure. The depicted topology 1000 comprises 2 railpods, in which a railpod comprises 64 rack units and each rack unit supports 72 GPUs. The depicted topology comprises 144 leaf switches, 144 spine switches, and 128 superspine switches.

FIG. 11 depicts a much larger topology, according to embodiments of the present disclosure. The depicted topology 1100 comprises 64 railpods, which each railpod comprising 64 units (e.g., 64 NVL72 units). Thus, the topology supports a total of 294,912 GPUs. The depicted topology comprises at total of 13,312 switches—4608 leaf switches, 4608 spine switches, and 4096 superspine switches.

As noted above, a NVL72 rack (or other GPU rack system) may be organized in railpods. In the embodiments depicted in FIG. 10 and FIG. 11, each railpod comprises 64 racks. Each NVL72 rack is connected with one link to 72 leaf switches, one per each rail. In one or more embodiments, the topology includes also 72 groups of spine switches, each comprising two (2) to 64 switches, depending on the size of the cluster, groups represented as columns in FIG. 10 and FIG. 11. Within a rail, each leaf switch may be connected to the spine switches with a number of links dependent on the GPU cluster scale, from 32 (small scale) to 1 (largest scale). In the depicted embodiments, the leaf switches are fully populated, with all 128 ports used. Each of the rows of spine switches may be connected to a corresponding row of 64 superspine switches. In one or more embodiments, the spine switches are fully populated, with all 128 ports used, while the superspine switches may be sparsely populated, with just 72 out of 128 ports used.

Table 2 compares two topologies (the NVIDIA topology and an embodiment of the current patent disclosure) for a cluster of 9216 GPUs with radix 64 switches. The embodiment topology is better for all the considered parameters.

TABLE 2
Topologies Comparison

| | | Improved Topology |
|---|---|---|
| | NVIDIA Topology | Embodiment |
| Latency/Traffic | 3 hops for Intra-Pod | 1 hop for Intra-Pod |
| Management | communications | communications |
| | 5 hops for Inter-Pod | 3 hops for Inter-Pod |
| | communications | communications |
| Number of Switches | 944 | 832 |
| Scale-out fabric Racks | 73 | 48 |
| Scalability | Up to 18,432 GPUs | Up to 36,864 GPUs |
| 3rd tier may be | No | Yes |
| oversubscribed | | |

Note that the NVIDIA topology underutilizes the leaf switches (i.e., 36 ports out of 64 ports are used), while the improved topology embodiment fully utilizes the leaf switches and preferentially shifts the underutilization to the lesser used superspine tier. Note also that there are more leaf switches than superspine switches. Therefore, it is much more efficient to have better utilization of the larger resource.

Table 3 compares the scalability properties of two topologies with radix 64 switches. Note that the improved topology scales better and requires fewer switches.

TABLE 3
Topologies Scalability

| | | | Improved Topology | |
|---|---|---|---|---|
| | NVIDIA | | Embodiments | |
| Scale | # of Switches | # of Tiers | # of Switches | # of Tiers |
| 36,864 GPUs | — | | 3328 | 3 |
| 18,432 GPUs | 1888 | 3 | 1664 | 3 |
| 9216 GPUs | 944 | 3 | 832 | 3 |
| 4608 GPUs | 472 | 3 | 416 | 3 |
| 2304 GPUs | 236 | 3 | 208 | 3 |
| 1152 GPUs | 118 | 3 | 68 | 2 |
| 576 GPUs | 56 | 2 | 34 | 2 |
| 288 GPUs | 28 | 2 | 17 | 2 |

### 3. Cabling Embodiments

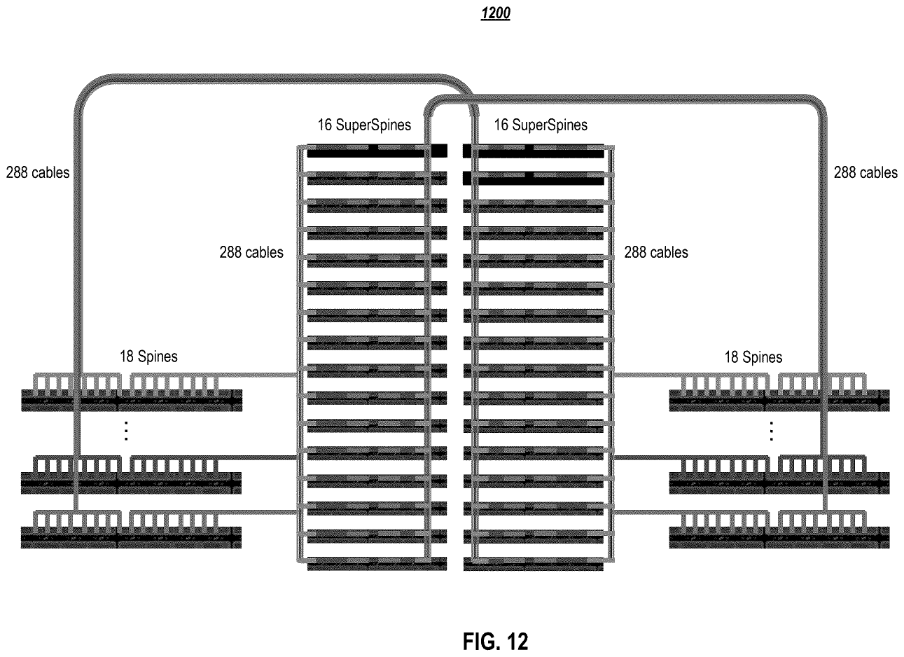

In addition to the improved topologies, one may consider how these improved topologies may be cabled relative to the use of copper and/or optical cables. Considering radix 64 switches, if the switches have cages hosting individual ports (e.g., they use QSFP (Quad Small Form-factor Pluggable) connectors, which are compact, hot-pluggable transceivers), copper cables may be used between the spines and superspine racks as shown in FIG. 12.

With this copper cabling scheme, an improved topology embodiment may achieve the same cabling economy as the current state of the art. However, for the specific case of the QM 9700 InfiniBand switch (or a similar style switch), this copper scheme may be limited because the switch uses OSFP cages, each hosting two ports (i.e., double ports), and the improved topology embodiment connects individual ports between spines and superspines.

In one or more embodiments, this issue may be addressed to allow the use of copper cables with QM 9700-like switches by having two parallel connections between each port of the spine and superspine switches. Such embodiments reduce the scaling of the improved topology implementations to be the same as the NVIDIA proposed topology (i.e., the maximum scale is 18K GPUs with radix 64 switches).

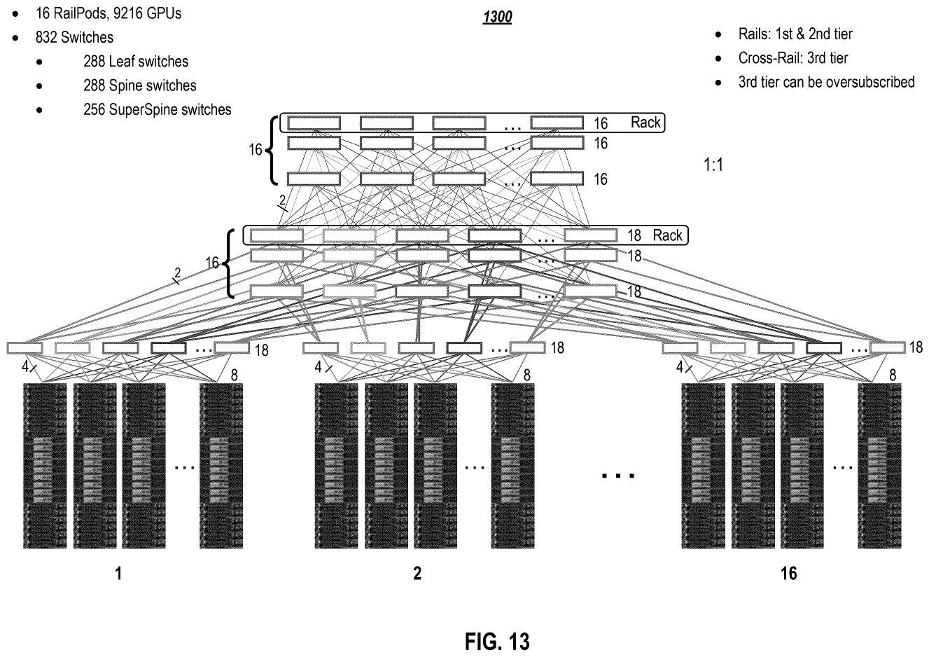

FIG. 13 depicts an updated topology, according to embodiments of the present disclosure. Specifically, FIG. 13 show an improved topology for 9216 GPUs allowing copper cabling, according to embodiments of the present disclosure. The NVL72 rack may be organized in smaller railpods, each comprising 8 racks. Each NVL72 rack may be connected with 4 links to 18 leaf switches, one per each rail. The topology 1300 may also comprise 18 groups/rails of spine switches, each comprising 16 switches—groups represented as columns in FIG. 13.

Within a rail, each leaf switch may be connected to the 16 spine switches with two links. The leaf switches may be fully populated, with all 64 ports used. Each of the 16 rows of spine switches may be connected to a corresponding row of 16 superspine switches. In one or more embodiments, the spine switches are fully populated, with all 64 ports used—while the superspine switches may be sparsely populated, with just 36 out of 64 ports used.

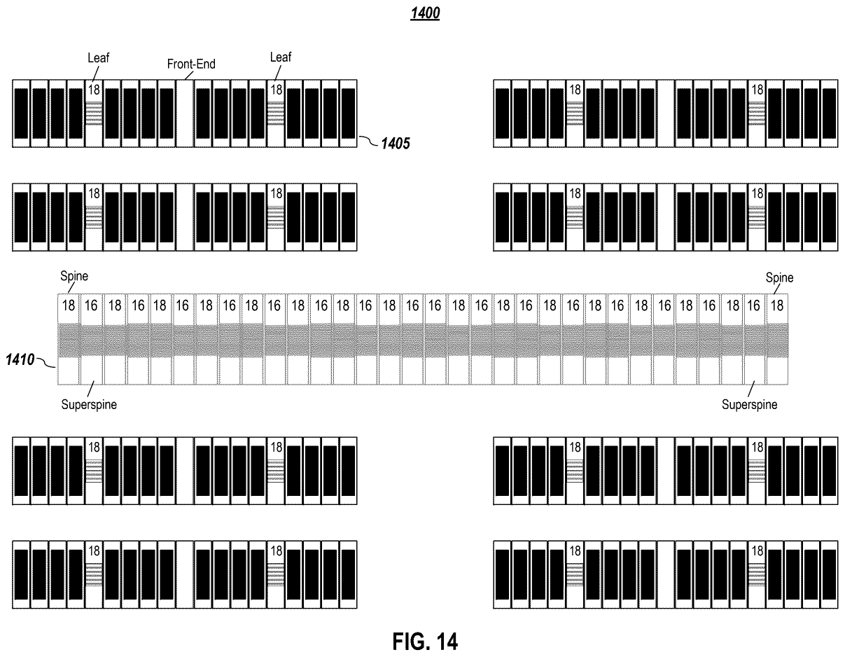

FIG. 14 depicts an example rack design for a topology depicted in FIG. 13, according to embodiments of the present disclosure. Note that the leaf switches may be closely housed with the GPU racks in a railpod 1405. The core 1410 may comprise alternating sets of spine switches and superspine switches, although other configurations may be used.

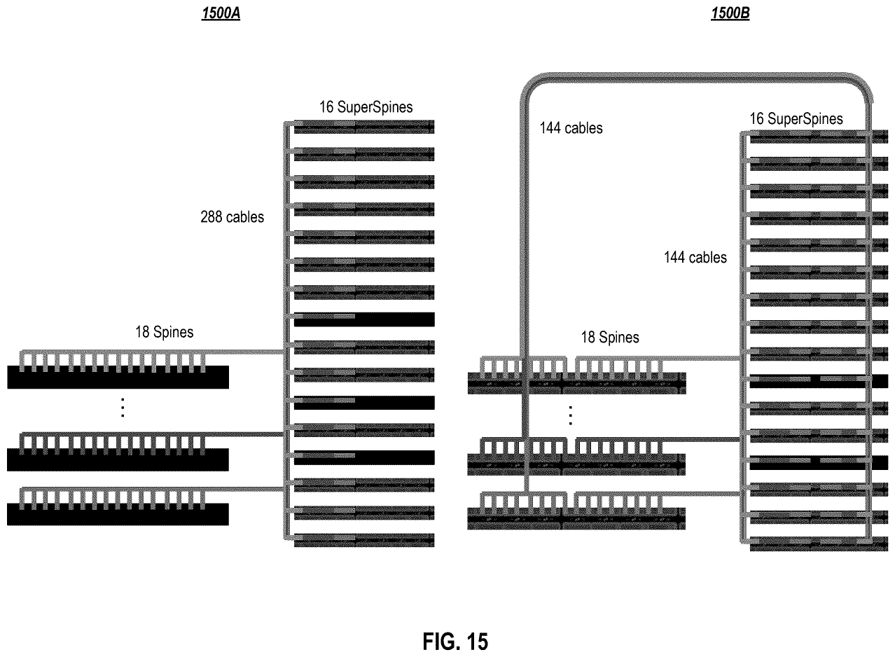

FIG. 15 depicts two ways (1500A and 1500B) to use double density copper cables between spines and superspine switches to support a topology depicted in FIG. 13, according to embodiments of the present disclosure. The depicted embodiments are using double density cables, which supports 800 Gb/s.

Table 4 compares the two topologies for a cluster of 9216 GPUs with radix 64 switches. The optimized topology appears to be better for all the considered parameters.

TABLE 4
Topologies Comparison

| | | Improved Topology |
|---|---|---|
| | NVIDIA Topology | Embodiments |
| Latency/Traffic | 3 hops for Intra-Pod | 1 hop for Intra-Pod |
| Management | communications | communications |
| | 5 hops for Inter-Pod | 3 hops for Inter-Pod |
| | communications | communications |
| Number of Switches | 944 | 832 |
| Scale-out Fabric Racks | 73 | 48 |
| Scalability | Up to 18432 GPUs | Up to 18432 GPUs |
| Optical cables/ | 18,432/13,824/4108 | 18,432/13,824/4108 |
| Transceivers/ | | |
| Copper cables | | |
| 3^{rd} tier may be | No | Yes |
| oversubscribed | | |

Table 5 compares the scalability properties of the two topologies with radix 64 switches.

TABLE 5
Topologies Scalability

| | | | Improved Topology | |
|---|---|---|---|---|
| | NVIDIA | | Embodiment | |
| Scale | # of Switches | # of Tiers | # of Switches | # of Tiers |
| 18432 GPUs | 1888 | 3 | 1664 | 3 |
| 9216 GPUs | 944 | 3 | 832 | 3 |
| 4608 GPUs | 472 | 3 | 416 | 3 |
| 2304 GPUs | 236 | 3 | 208 | 3 |
| 1152 GPUs | 118 | 3 | 104 | 3 |
| 576 GPUs | 56 | 2 | 34 | 2 |
| 288 GPUs | 28 | 2 | 17 | 2 |

As the two tables above show, embodiments of the updated topology improve several factors, including but not limited to networking efficiency, number of devices needed, performance, costs (e.g., number of devices, cabling, infrastructure costs, heating/cooling, etc.), among other factors.

Table 5 compares the scalability properties of the two topologies with radix 64 switches.

TABLE 5
Topologies Scalability

| | | | Improved Topology | |
|---|---|---|---|---|
| | NVIDIA | | Embodiment | |
| Scale | # of Switches | # of Tiers | # of Switches | # of Tiers |
| 18432 GPUs | 1888 | 3 | 1664 | 3 |
| 9216 GPUs | 944 | 3 | 832 | 3 |
| 4608 GPUs | 472 | 3 | 416 | 3 |
| 2304 GPUs | 236 | 3 | 208 | 3 |
| 1152 GPUs | 118 | 3 | 104 | 3 |
| 576 GPUs | 56 | 2 | 34 | 2 |
| 288 GPUs | 28 | 2 | 17 | 2 |

As the two tables above show, embodiments of the updated topology improve several factors, including but not limited to networking efficiency, number of devices needed, performance, costs (e.g., number of devices, cabling, infrastructure costs, heating/cooling, etc.), among other factors.

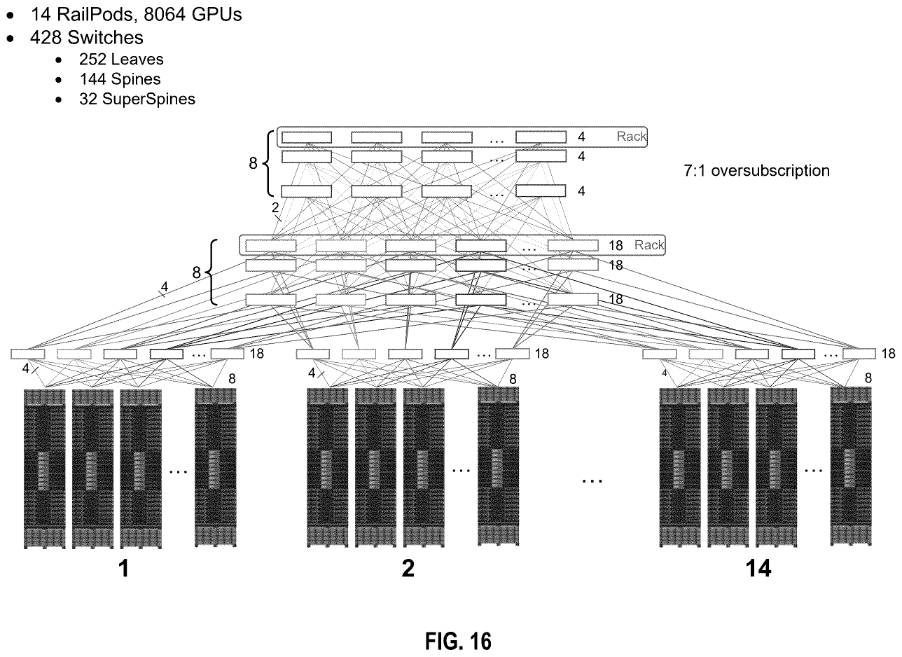

As previously noted, embodiments may utilize oversubscription. FIG. 16 depicts an example topology with oversubscription, according to embodiments of the present disclosure. The topology supports a cluster of 8064 GPUs and uses a 7 to 1 (7:1) oversubscription at the superspine switch tier. It shall be noted that different oversubscription ratios may be used, particularly depending upon the scale of the cluster being supported. For example, supporting a cluster of 288 GPUs may use two tiers and have a 4:1 oversubscription at the top tier, while supporting a cluster of 1152 GPUs may use two tiers and have a 5.3:1 oversubscription at the top tier.

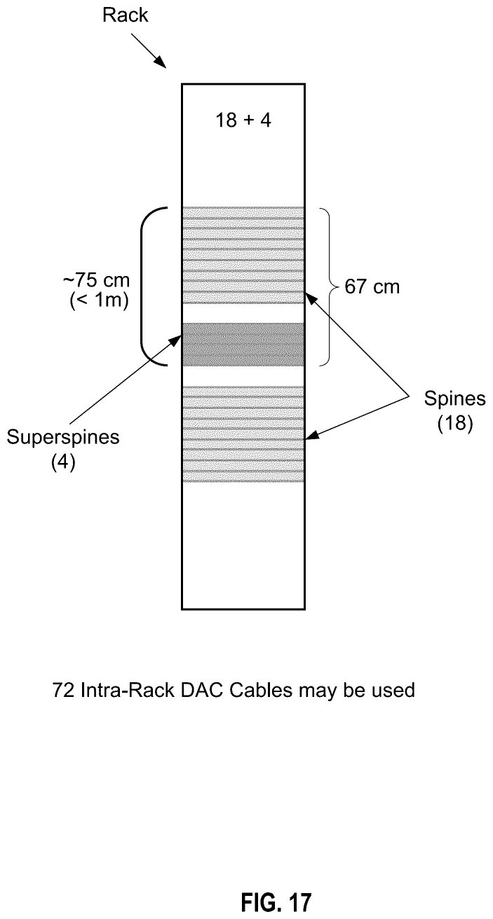

FIG. 17 depicts a possible racking solution for the spine and superspine switches, according to embodiments of the present disclosure. As depicted, a single rack may house 18 spine switches and 4 superspine switches. Since these switches are housed within a rack, direct attach copper (DAC) cables may be used given the short travel lengths.

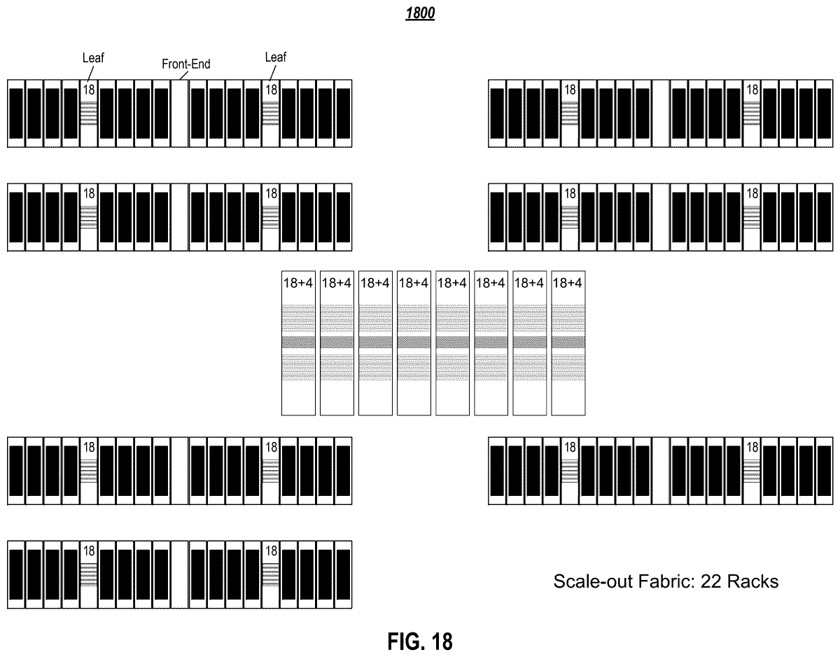

FIG. 18 depicts an example rack implementation for this topology, according to embodiments of the present disclosure. Note that a total of 22 racks are needed to house the equipment for the scale-out fabric of FIG. 16. By way of comparison, a cluster comprising the same number of GPUs using NVIDIA's topology requires 65 racks for its scale-out fabric. The table in

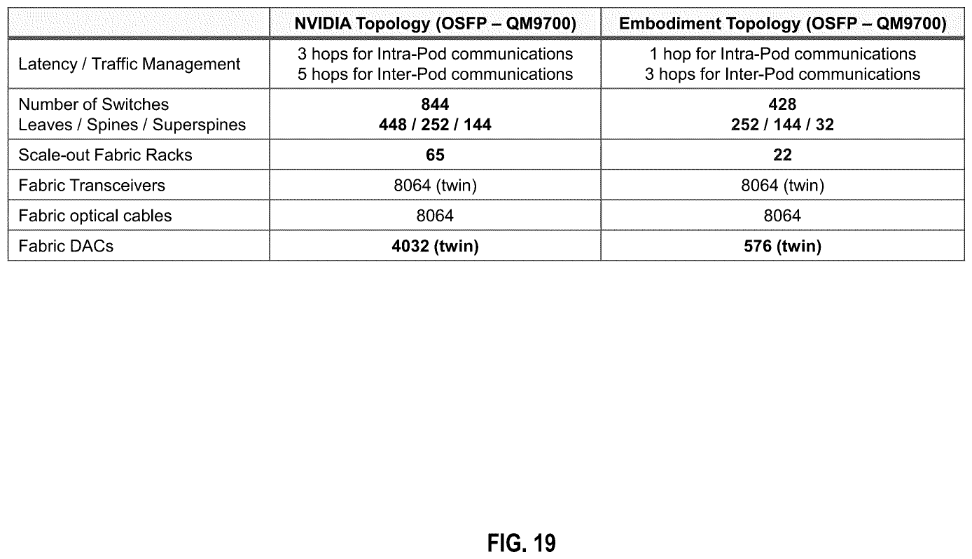

FIG. 19 compares the two topologies. Note that the embodiment topology of FIG. 16 uses far fewer switches and cables than the NVIDIA topology that supports the same number of GPUs.

Not only do the embodiments of the present disclosure operate more effectively by requiring few hops, but they also use fewer switches. Using fewer switches save numerous resources—physical space, number of racks, less power to run because there are fewer devices, less power need for infrastructure (e.g., cooling), fewer cables, etc.

### 4. Topology Design/Implementation Method Embodiments

One skilled in the art shall recognize a number of innovative aspects of embodiments of the present disclosure. One innovative aspect of one or more embodiments is the handling of network topologies given unique situations. For example, for AI/ML systems that are extremely computationally intensive and that require sharing or passing of data for model training and model deployment, speed and efficiency in data handling is not only critical but it dramatically impacts overall timing and costs.

It should also be noted that additional factors complicate the topology design. For example, a computational-intensive center, such as the ones used for AI/ML systems, may comprise different networks—a first network, which may be an inter-node fabric (e.g., a scale-up network), that connects all compute nodes of a group (e.g., all compute nodes of a rack or a set of racks) and a second network (e.g., a scale-out fabric), which connects the groups (e.g., railpods) of compute nodes. As noted above, a GPU on a compute node like those discussed herein (e.g., FIGS. 2-5) leverages two different communication interfaces: a scale-up interface and a scale-out interface.

Another complication or factor may be differences between these networks. For example, data may be preferably communicated by one network (e.g., the scale-up fabric) over the other network (e.g., the scale-out fabric). The scale-up interface may have a bandwidth approximately an order of magnitude higher than the scale-out interface.

Another complication or factor may be differences between the networks. For example, data may be preferably communicated by one network (e.g., the scale-up fabric) over the other network (e.g., the scale-out fabric). Accordingly, strategic decisions implemented herein take into account these various factors to achieve improved topologies that exhibit at least the benefits discussed above.

Also, differences in the number of ports between a rack of compute nodes or a set of racks (i.e., a railpod) on one hand and network information handling systems (e.g., switches) on the other hand complicate the topology design. When the difference in port numbers between a group of end devices and switches is not a readily divisible/multiple integer, it complicates topologies when trying to be efficiency and cost effective. Consider the following illustration.

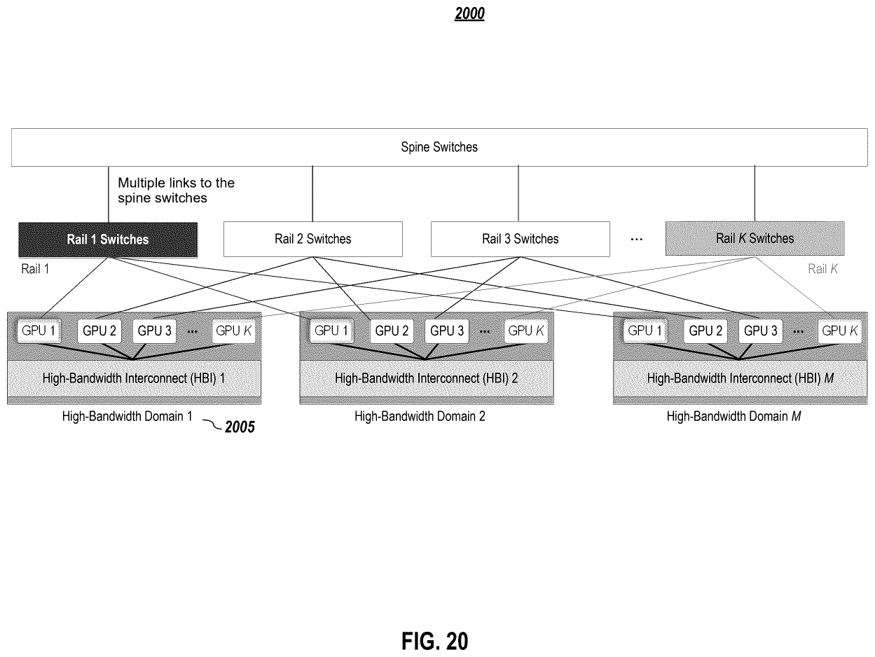

FIG. 20 depicts a cluster 2000 of GPUs that utilize network rails, according to embodiments of the present disclosure. A group of GPU s may be interconnected through their scale-up interfaces may form a high-bandwidth domain (e.g., high-bandwidth domain 1 2005). In the depicted example, the GPUs within a high-bandwidth domain may be indexed from 1 to K. Note also that there may be M number of domains.

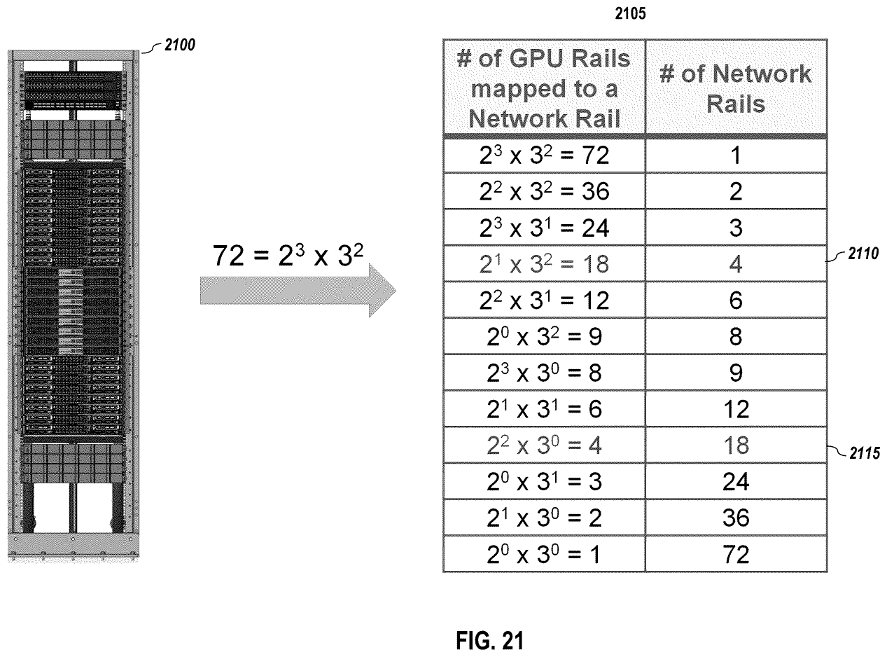

As noted above, the number of ports of a set of GPU s may have a mismatch between the number of ports of switches, which is illustrated in FIG. 21. By way of illustration of the port number mismatch, consider a NVL72 rack 2100 that is graphically depicted. It contains 72 ports, which may be represented in prime factorization as 23×32. In contrast, the radix of most switches base 2 (e.g., 32 ports, 64 ports, 128 ports, etc.), which creates a mismatch. The chart 2105 depicts the various prime factorization of the number of GPU rails mapped to the number of network rails. A GPU rail may be defined as a set of GPUs with the same index on different high bandwidth domains, and a network rail (or rail) may be defined as a set of switches in the scale-out fabric through which one or more GPU rails are connected. Different options may be selected. Prior approaches use a limited number of network rails. For example, as noted above, NVIDIA suggest using 4 network rails mapped to 18 GPU rails (row 2110). However, in one or more embodiments, each network rail should minimize the number of GPU rails mapped over it; at large scales, each network rail may preferably carry one GPU rail. Therefore, an example of an improved topology may utilize many more rails (e.g., row 2115 in which 18 network rails are used).

Another factor to consider is the interplay between using rails and that there are two distinct networks employed. Embodiments appreciate that the scale-up fabric-not the scale-out fabric—should be the default pathway to cross rails. In one or more embodiments, rails may not be oversubscribed and may be extended from the first tier to one or more additional tiers (e.g., to the third tier, depending upon embodiment). In one or more embodiments, crossing rail in the scale-out fabric (if it happens) occurs at the second or third tier, depending on embodiment and data traffic. Also, in one or more embodiments, if rails do not extend to the tier where scale-out cross rail happens, that tier may be oversubscribed because, at least in part, that tier is used when other links/pathways have failed.

Other factors to consider are the physical configuration/layout of the compute node/GPUs, leaf switches, spine switches, and if needed, superspine switches. The number and arrangement (e.g., same rack, adjacent rack, or distance rack) of the devices, which may be the same and/or different devices, including same devices functioning in different capacities can dramatically affect cost and performance. For example, the distance between devices may affect whether copper cables can be used, which are less expensive than optical cables but support a much shorter reach (e.g., around 2 meters for passive copper cables and 3-5 meters for active copper cables). Consider the layout depicted in FIG. 6. The fewer number of leaf switches allows them to be placed closer to the end devices, which allows for copper cabling. However, optical cabling (and switch transceivers) must be used for the other switches. In contrast, in one or more embodiments, copper cabling may be used between spine and superspine switches. Consider the spine-superspine switch core with two railpods comprising eight racks each. Such a system can support 1152 GPUs and uses 104 switches (36 leaf switches, 36 spine switches, and 31 superspine switches). The close proximity of these switches allows for the use of copper cables. FIG. 15 also depicts and discusses the use of copper cabling, according to embodiments of the present disclosure. It shall be noted that, depending upon the size of the cluster and the embodiment, copper cables may be used in other places, such as between leaf switches and spine switches.

Topology embodiments herein contemplate and consider these factors for the improved topologies.

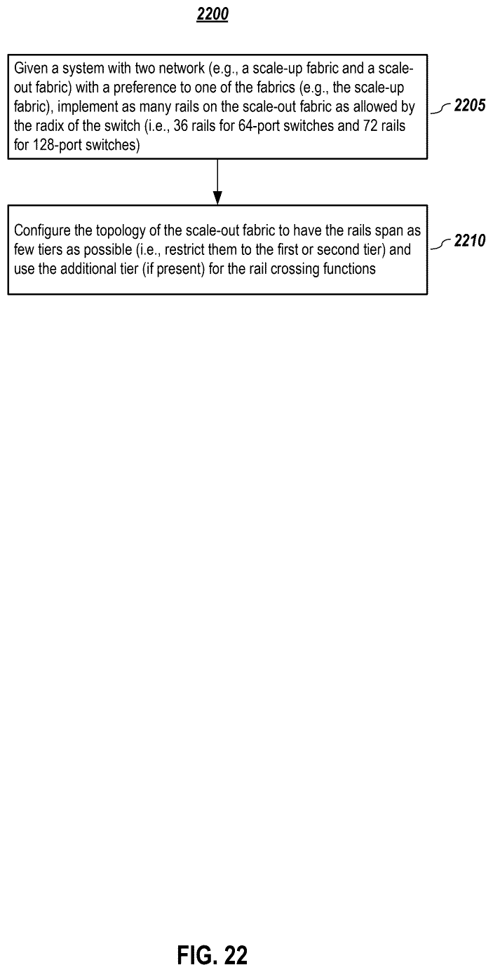

FIG. 22 depicts a methodology for configuring a topology, according to embodiments of the present disclosure. In one or more embodiments, strategic implementations may comprise having (2205) as many rails as allowed by the radix of the switches used in the scale-out fabric (e.g., 36 rails for 64-port switches, 72 rails for 128-port switches, etc.). In one or more embodiments, strategic implementations may also comprise having the rails span (2210) a minimum number of tiers possible (e.g., restricting them to the first tier or to the first and second tiers) and use any additional tier or tiers for the rail crossing function.

In one or more embodiments, given a set of one or more railpods, in which each railpod comprises a plurality of racks and each rack comprises a set of compute nodes, n number of ports, and a first network that interconnects processors of the compute nodes, a method for configuring a network topology may comprise the following steps. The processor (e.g., GPUs) of each rack may be connected via a number of connections (c) to a set of leaf switches (l) in which: c xl equals an integer divisor of the number of ports (n) of a rack; each leaf switch forms a rail; and the number of ports of a leaf switch of the set of leaf switches is not an integer multiple of number of ports (n) of a rack. Responsive to extending the rails to a second tier comprising spine switches (e.g., depending upon the size of the cluster), the leaf switches may be connected to sets of two or more spine switches, in which: the number of sets of two or more spine switches is an equal number as leaf switches; each set of two or more spine switches corresponds to a rail; and within a rail, each leaf switch is connected to the spine switches with a number of connections dependent upon a cluster scale. In one or more embodiments, each of the sets of spine switches may be connected to a corresponding row of superspine switches to facilitate data crossing rails.

### a) Radix 64 Switches Embodiments

For topologies that are utilizing radix 64 switches and a rack comprising compute nodes having a total of 72 ports, the following example methodology may be employed.
The racks (e.g., NVL72 racks) may be organized into railpods, in which each railpod comprises 16 racks.
Each rack may be connected with two links to a set of 36 leaf switches, in which each leaf switch represents one network rail.
The leaf switches may be connected to 36 groups of spine switches, one per each network rail, and each group of spine switches comprise two to 32 switches, depending on the size of the cluster (in which a cluster represents the total number of GPUs in the network).
Within a rail, each leaf switch is connected to the spine switches with a number of links dependent on the GPU cluster scale—from 16 (small scale) to 1 (largest scale).
Note that the leaf switches are fully populated, in which all 64 ports of each leaf switch is used.
Each of the 36-switch rows of spine switches is connected to a corresponding row of 32 superspine switches for the rail crossing function;
Note that, in one or more embodiments, the spine switches may be fully populated, with all 64 ports used, while the superspine switches may be sparsely populated (e.g., 36 out of 64 ports used).
In one or more embodiments, the superspine tier may be oversubscribed for rail crossing without affecting performances.

### b) Radix 128 Switches Embodiments

For topologies that are utilizing radix 128 switches and a rack comprising compute nodes having a total of 72 ports, the following example methodology may be employed.
The racks (e.g., NVL72 racks) may be organized into railpods, in which each railpod comprises 64 racks.
Each rack may be connected with two links to a set of 72 leaf switches, in which each leaf switch represents one network rail.
The leaf switches may be connected to 72 groups of spine switches, one per each network rail, and each group of spine switches comprises two to 64 switches, depending on the size of the cluster.
Within a rail, each leaf switch may be connected to the spine switches with a number of links dependent on the GPU cluster scale—from 32 (small scale) to 1 (largest scale).
Note that the leaf switches are fully populated, with all 128 ports used.
Each of the 72-switch rows of spine switches may be connected to a corresponding row of 64 superspine switches for the rail crossing function. In one or more embodiments, the spine switches may be fully populated, with all 128 ports used, while the superspine switches are sparsely populated (e.g., 72 out of 128 ports used).

In one or more embodiments, the superspine tier may be oversubscribed for rail crossing without affecting performances.

### 5. Embodiments When Small Form Factor Pluggable Modules Are Used

Note that alternative embodiments of topologies exists for switches using small form factor pluggable modules, such as OSFPs (Octal Small Form Factor Pluggable).

### a) Radix 64 Switches Embodiments with OSFPs

For topologies that are utilizing radix 64 switches with OSFPs and a rack comprising compute nodes having a total of 72 ports, the following example methodology may be employed.
The racks (e.g., NVL72 racks) may be organized into railpods, in which each railpod comprises 8 racks.
Each NVL72 rack may be connected with four links to 18 leaf switches, one per each rail.
The leaf switches may be connected to 18 groups of spine switches, one per each rail, and each group of spine switches comprise two to 32 switches, depending on the size of the cluster.
Within a rail, each leaf switch may be connected to the spine switches with a number of links dependent on the GPU cluster scale—from 16 (small scale) to 1 (largest scale).
Note that, in one or more embodiments, the leaf switches are fully populated, with all 64 ports used.
Each of the 18-switch rows of spine switches may be connected to a corresponding row of 16 superspine switches for the rail crossing function.
In one or more embodiments, the spine switches are fully populated, with all 64 ports used, while the superspine switches may be sparsely populated (e.g., 36 out of 64 ports used).
The superspine tier may be oversubscribed for rail crossing without affecting performances.

### b) Radix 128 Switches Embodiments with OSFPs

For topologies that are utilizing radix 64 switches with OSFPs and a rack comprising compute nodes having a total of 72 ports, the following example methodology may be employed.
The racks (e.g., NVL72 racks) may be organized into railpods, in which each railpod comprises 32 racks.
Each rack may be connected with one link to 36 leaf switches, one per each rail.
The leaf switches may be connected to 36 groups of spine switches, one per each rail, and each group of spine switches comprise two to 32 switches, depending on the size of the cluster.
Within a rail, each leaf switch may be connected to the spine switches with a number of links dependent on the GPU cluster scale—from 32 (small scale) to 1 (largest scale).
In one or more embodiments, the leaf switches are fully populated, with all 128 ports used.
Each of the 36-switch rows of spine switches may be connected to a corresponding row of 32 superspine switches for the rail crossing function.
In one or more embodiments, the spine switches are fully populated, with all 128 ports used, while the superspine switches may be sparsely populated (e.g., 72 out of 128 ports used).
The superspine tier may be oversubscribed for rail crossing without affecting performances.

### C. High-Density Switching Embodiments for Scale-Out Fabrics

### 1. General Introduction

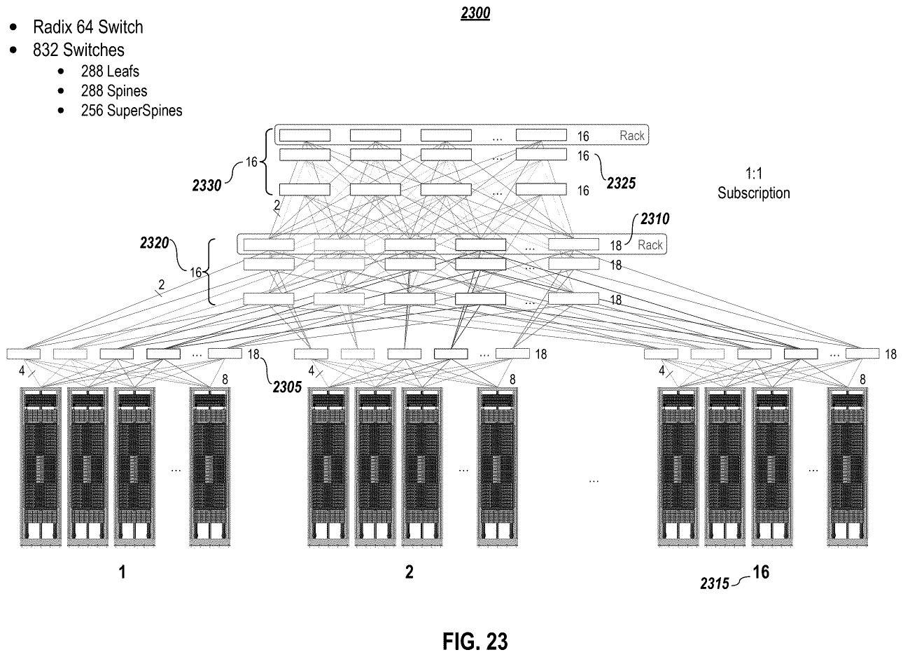

As discussed in the prior section rail-improved scale-out fabrics can help improve complex high compute topologies. FIG. 23 shows a scale-out fabric topology for a 9216 GPUs cluster built using a NVIDIA NVL72 system (or an NVL72-like system) and 64-port switches (e.g., Dell Z9664 switches), according to embodiments of the present disclosure. The depicted embodiment represents a rail-optimized/rail-improved topology with 18 rails. As discussed in the prior section, using switches with a radix that is a power of 2 (e.g., 64) does not allow full utilization of all switch ports when dealing with a rack system like the NVL72, which includes the prime number 3 in its number of NICs (72=23×32). In this case, the superspine switches are underutilized (only 36 out of 64 ports used), while spine switches and leaf switches are fully utilized.

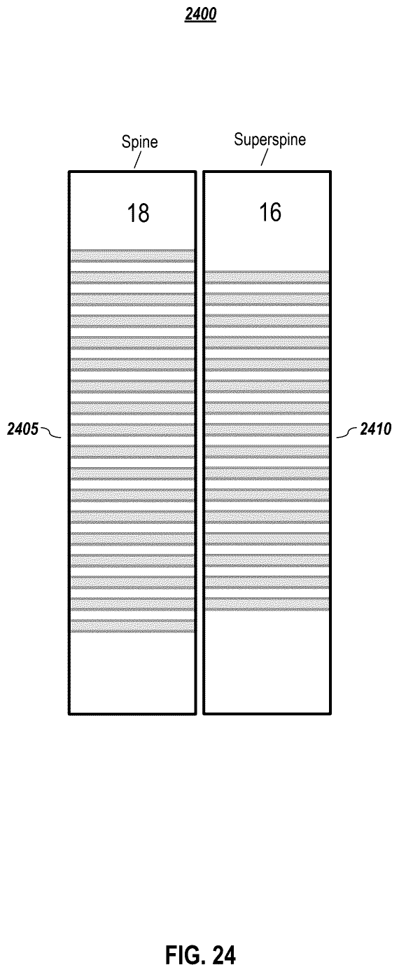

As shown in FIG. 23, the number of rails (18 in this embodiment) 2305 is reflected in the number of spine columns (also 18) 2310, and the number of railpods (16 in this embodiment) 2315 is reflected in the number of spine rows (also 16) 2320. Each spine row of switches is interconnected by a correspondent row of superspine switches (16) (e.g., row 2325) that reduces the prime number 3 to the power of 2 that is the switch radix. This results in 16 sets 2330, each set comprising 18 spine switches coupled with 16 superspine switches. If a switch like the Dell Z9664 is used (which is a 2 rack unit (RU) switch), it is possible to install the 18 spine switches in a rack (i.e., vertical space of 36 RUs) 2405, and the related 16 superspine switches may be housed in an adjacent rack (i.e., vertical space of 32 RUs) 2410, as shown in FIG. 24.

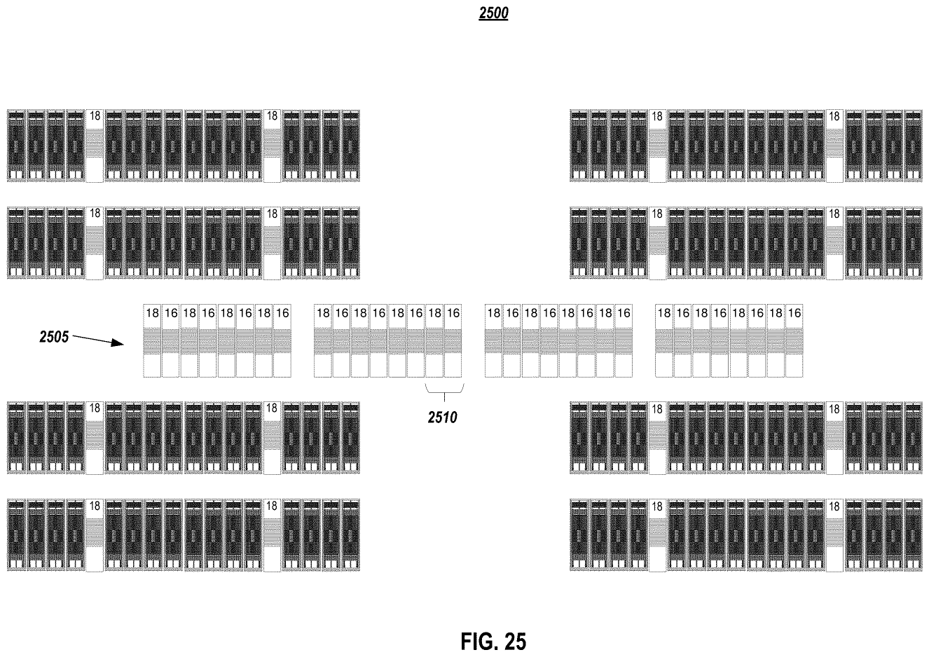

An embodiment of a resulting rack layout is shown in FIG. 25, which highlights the 16 two-rack sets of spine-superspine switches 2505, according to embodiments of the present disclosure.

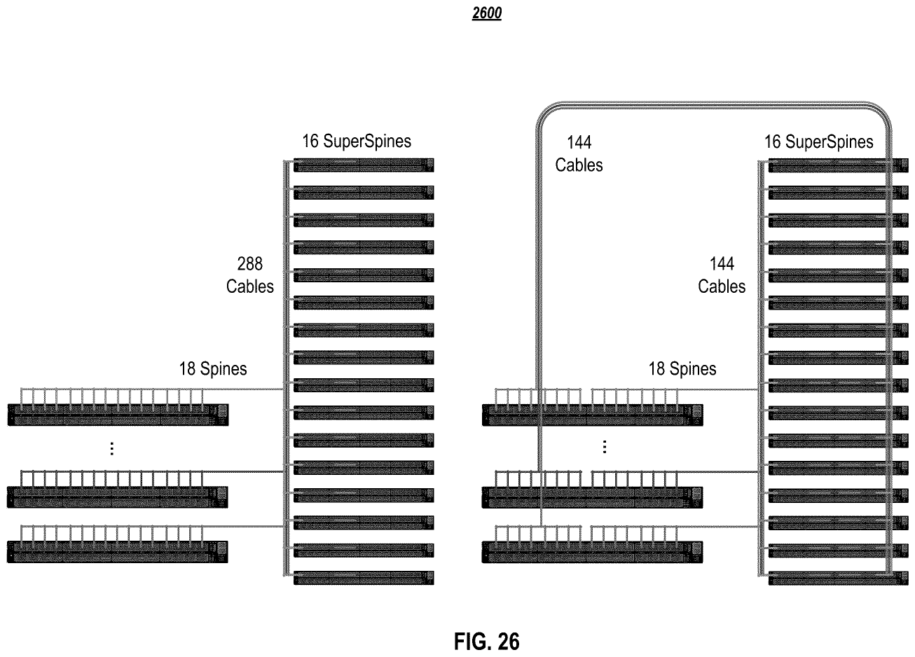

Being that the two racks of spine switches and superspine switches (e.g., two-rack set 2510) are adjacent, it is possible to use copper DAC cables to perform the related wiring. FIG. 26 shows two possible options routing the DAC cables, according to embodiments of the present disclosure.

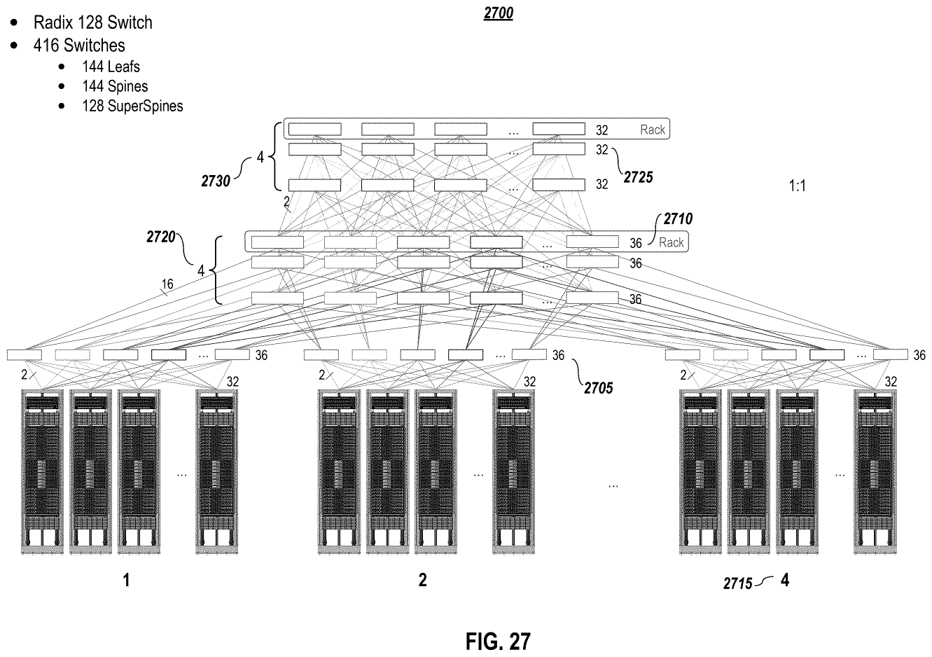

Moving to radix 128 switches, FIG. 27 depicts a scale-out fabric topology for a 9216 GPUs cluster built using a system like the NVIDIA NVL72 system and 128-port switches (e.g., Dell Z9864 switches), according to embodiments of the present disclosure. The depicted embodiment represents a rail-optimized/rail-improved topology with 36 rails 2705. Using switches with a radix that is a power of 2 (e.g., 128) does not allow fully utilizing all switch ports when dealing with a system like the NVL72 system, which includes the prime number 3 in its number of NICs (72=23×32). In this case, the superspine switches are underutilized (only 72 out of 128 ports used), while spine switches and leaf switches are fully utilized.

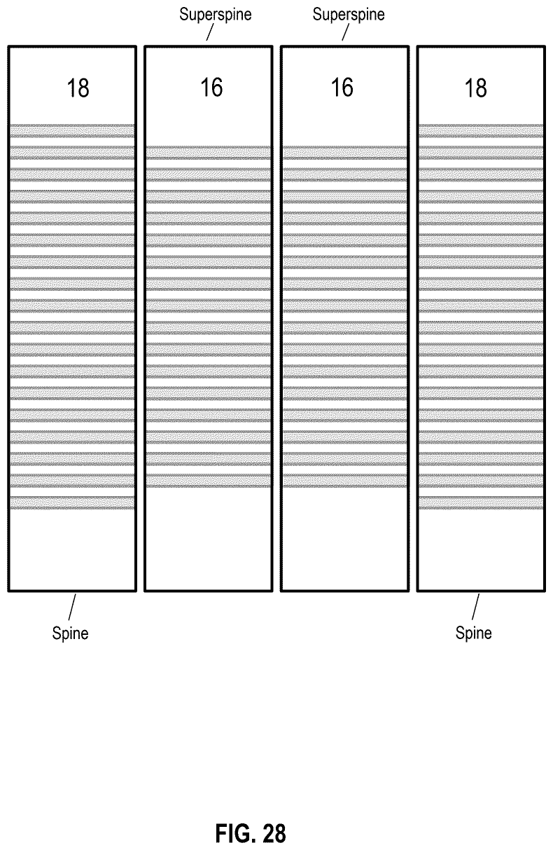

As shown in FIG. 27, the number of rails (36) 2705 is reflected in the number of spine columns (36) 2710, and the number of railpods (4) 2715 is reflected in the number of spine rows (4) 2720. Each spine row may be interconnected by a correspondent row of superspine switches (32) (e.g., superspine row 2725) that reduce the prime number 3 to the power of 2 that is the switch radix. This topology results in 4 sets (i.e., 2720 and 2730), each set comprising 36 spine switches (e.g., 2710) coupled with 32 superspine switches (e.g., 2725). Given that a Dell Z9864 switch is a 2RUs switch, four racks are needed to host the 36 spine switches and the 32 superspine switches. FIG. 28 depicts a four-rack set of spine-superspine switches, according to embodiments of the present disclosure.

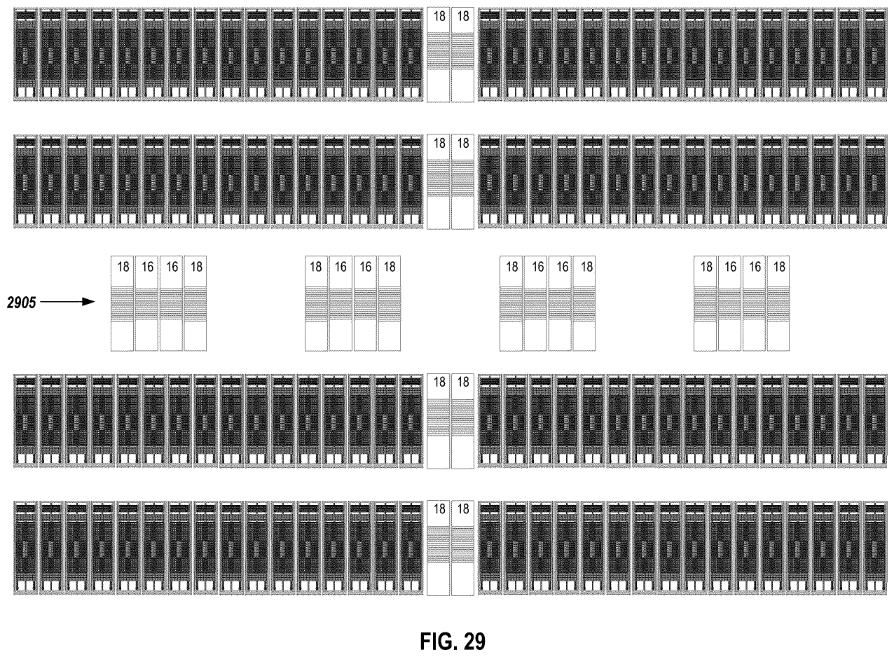

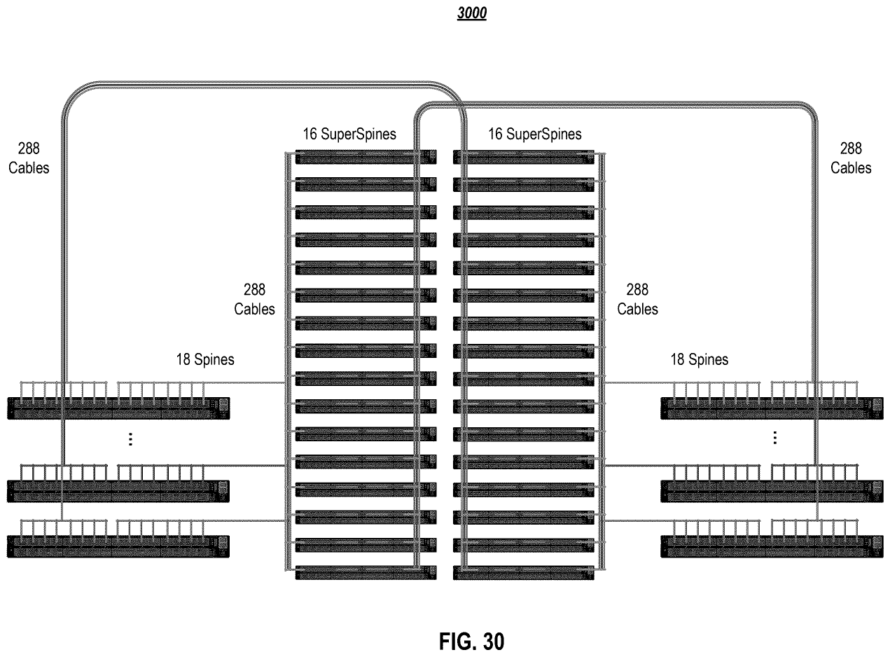

An example resulting rack layout is shown in FIG. 29, which highlights the four 4-rack sets 2905 of spine-superspine switches, according to embodiments of the present disclosure. Being that the racks of spines and superspine switches may be placed adjacent, it is possible to use copper DAC cables to perform the related wiring. FIG. 30 shows a possible way to route the cables, according to embodiments of the present disclosure.

Given that DAC copper cables are significantly bulkier than optical cables, the cabling shown in FIG. 26 and FIG. 30 are not trivial. Presented in the next section are embodiments that provide different and more compact solutions.

### 2. High-Density Switching Embodiments

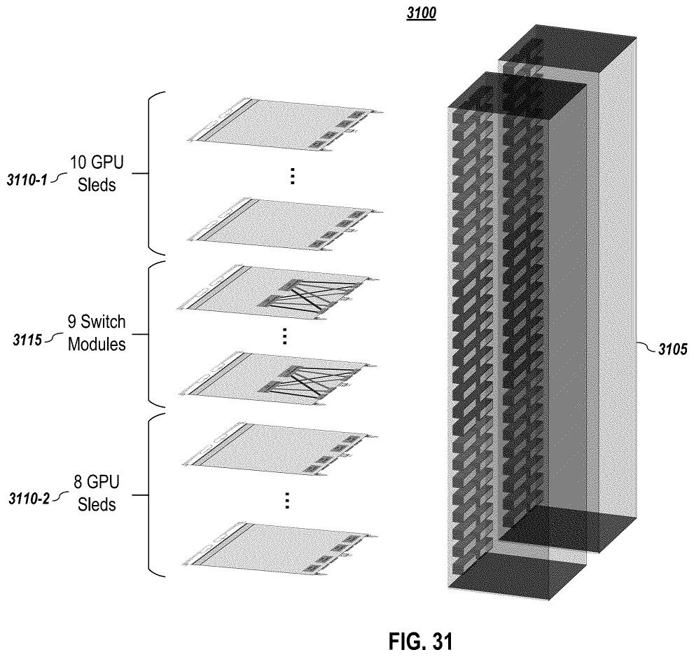

Consider the structure of the NVL72 system, which is graphically illustrated in FIG. 31. As shown, an NVL72 interconnects the 72 GPUs of the 18 GPU trays (or sleds) 3110 with the 9 NVSwitches 3115 present in the system 3100 through two passive cartridges 3105. As will be presented below, embodiments leverage passive cartridge embodiments to provide an interconnect cable system to interconnect switches (e.g., spine switches and superspine switches).

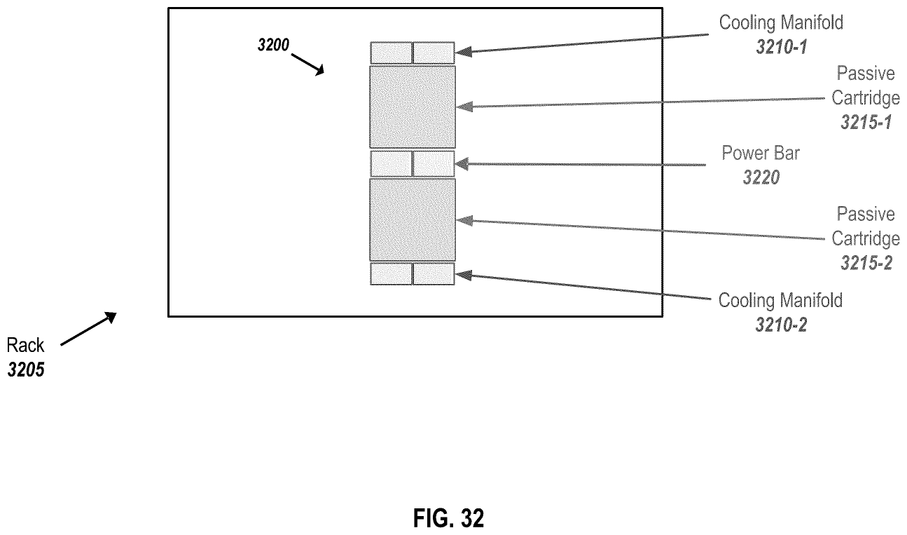

FIG. 32 shows a top view of a rack, according to embodiments of the present disclosure. In one or more embodiments, the rack may be adapted or modified from an Open Rack (OR) (e.g., OR version 3 rack), which is an Open Compute Project standard for a rack and power delivery architecture, but other racks may be used. In one or more embodiments, the rack may be modified to position in the interior (e.g., at or near the center) of the rack the cooling manifolds 3210, power bars 3220, and passive cartridge that contain cabling 3215. In a typical rack, these elements (i.e., the cooling manifolds 3210, the power bars 3220, and the passive cartridge 3215) are positioned at the back of the rack. However, in one or more embodiments, these elements are placed in the middle of the rack, and they may be either double or bidirectional. By locating the interconnect cable system 3200 in the interior of the rack, modules, such as switches and compute modules, may be installed on both the front and the back of the rack 3205.

In the depicted embodiment of FIG. 32, there are two passive cable cartridges 3215 installed in the interior/central region of the rack; cartridges that provide the signal connectivity between different switches (e.g., leaf switches, spine switches, superspine switches, or a combination thereof) within the rack.

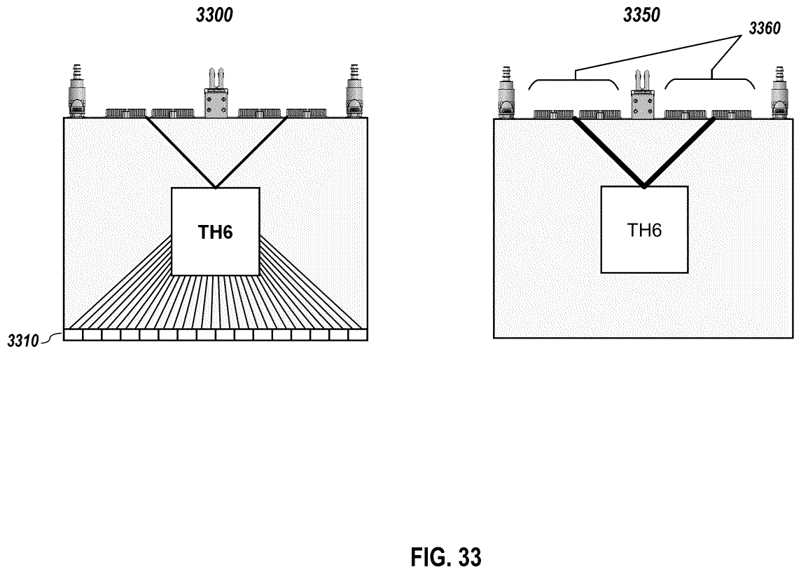

FIG. 33 graphically illustrates the structure of liquid cooled switches 3300 and 3350 for a modified rack using a Tomahawk-6 (TH6) switching A SIC (Application-Specific Integrated Circuit) by Broadcom Inc. of San Jose, California as an example, according to embodiments of the present disclosure. The TH6-200 has 256 ports capable of operating at 400 Gb/s or 128 ports capable of operating at 800 Gb/s, using 200 Gb/s SerDes (Serializer/Deserializer).

Switch 3300 depicts the structure of a first type of switch that may operate as a leaf switch, in which half of the TH 6 ports are connected to the front panel 3310. This means the front panel hosts 64 ports at 800 Gb/s, which can fit in 32 OSPF cages, requiring just 1 RU of vertical space. The remaining 64 ports operating at 800 Gb/s, are connected to high density connectors (e.g., the Paladin line of connectors from Corning) in the back of the switch. The illustration of switch 3350 shows the structure of a second type of switch that may operate as a spine switch or as a superspine switch, in which all the TH6 ports are connected to high density connectors (e.g., the Paladin® line of connectors by Amphenol Corporation of Nashua, New Hampshire) in the back 3360 of the switch.

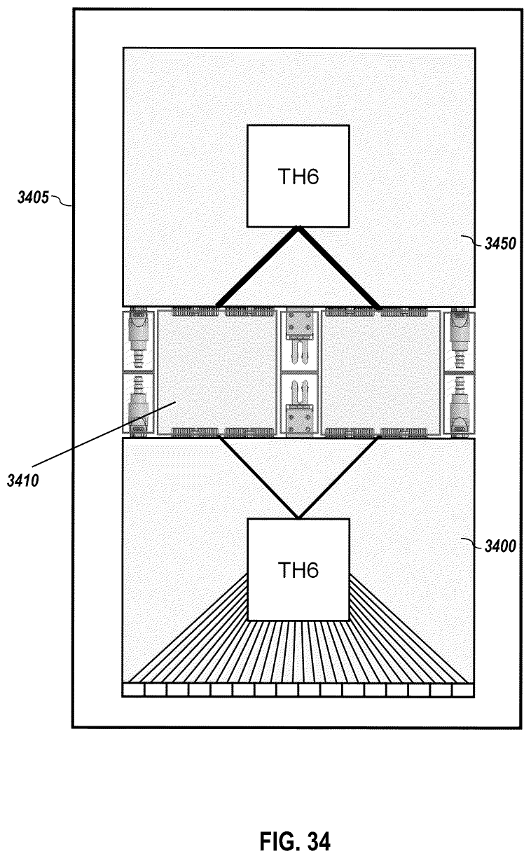

FIG. 34 depicts the two types of switches 3400 and 3450 installed in the rack 305 and interconnected by the passive cable cartridges of an interconnect cable system 3410, according to embodiments of the present disclosure. In one or more embodiments, the interconnect cable system 3410 supports or provide space for liquid cooling, which helps dissipate the generated by the modules installed in the rack.

### a) Embodiments of Homogenous Module Type Per Face of the Rack System

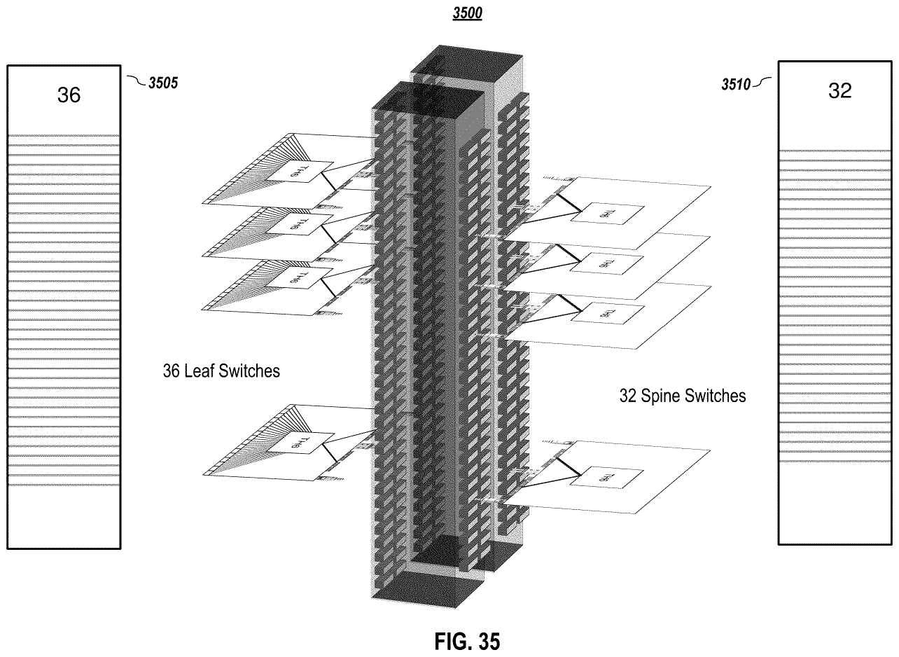

FIG. 35 shows a view of a rack switch design for 36 leaf switches (which may be used as spine switches in the topology of FIGS. 23) and 32 spine switches (which may be used as superspine switches in the topology of FIG. 23), according to embodiments of the present disclosure. The result is a rack with 36 front panels 3505 each with 32 OSFP (Octal Small Form Factor Pluggable) connectors, supporting a total of 2304 800GE (gigabit Ethernet) ports. Note that an additional benefit of the depicted embodiment is that all switches are fully serviceable—the leaf switches from the front 3505 of the rack and the spine switches from the back 3510.

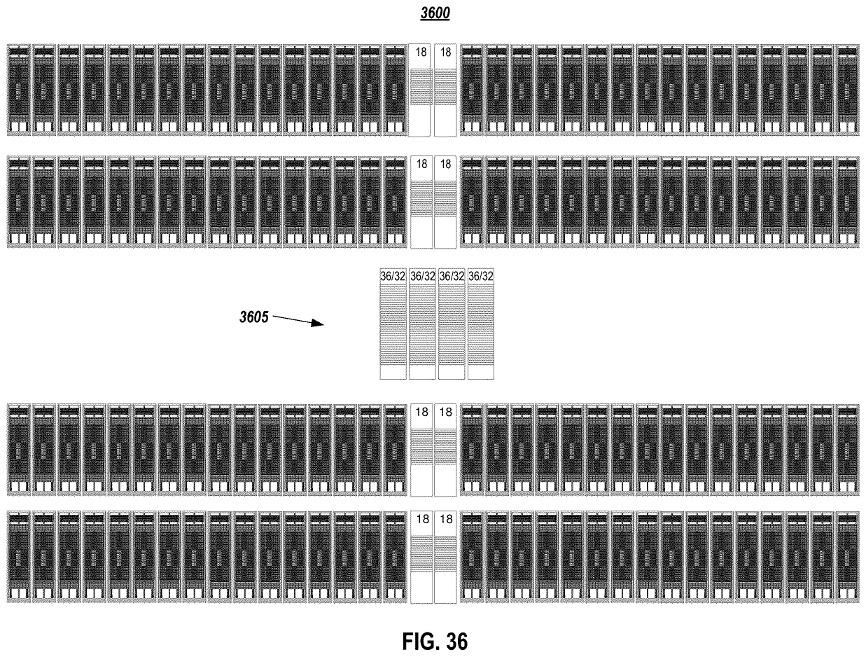

Note that with this rack switching embodiment, the rack layout of FIG. 25 simplifies to the rack layout 3600 shown in FIG. 36. Note that the core 3605 comprises 4 racks with each rack comprising 36 switches of a first type and 32 switches of a second type.

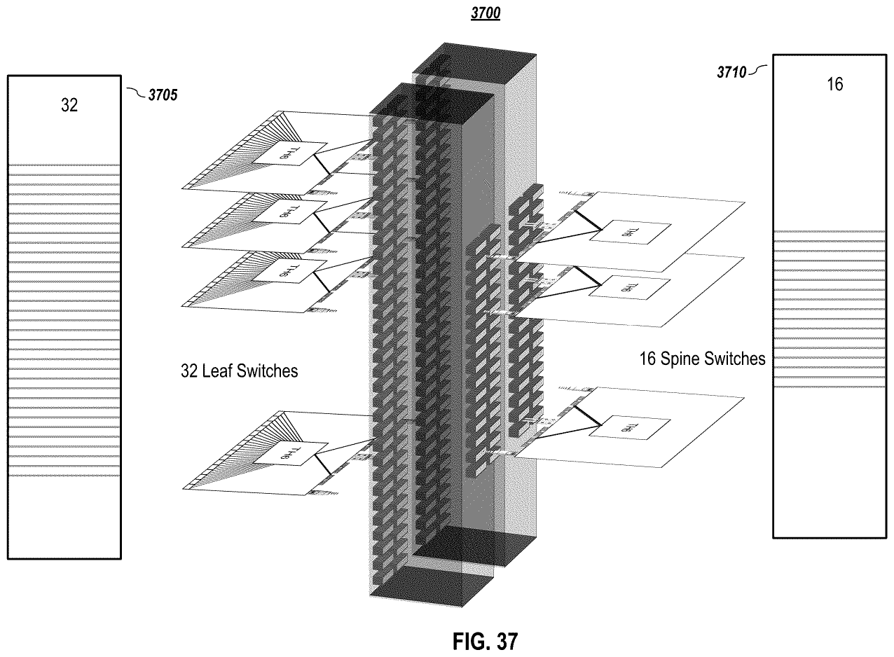

FIG. 37 depicts another rack switch configuration embodiment, with 32 leaf switches install a first face 3705 and 16 spine switches installed via a second face 3710, according to embodiments of the present disclosure. In one or more embodiments, this configuration supports 2048 800GE ports in 32 RUs and may be used also to support the 18/16 two-rack configuration shown in FIG. 24 when the scale-out fabric uses 18 rails.

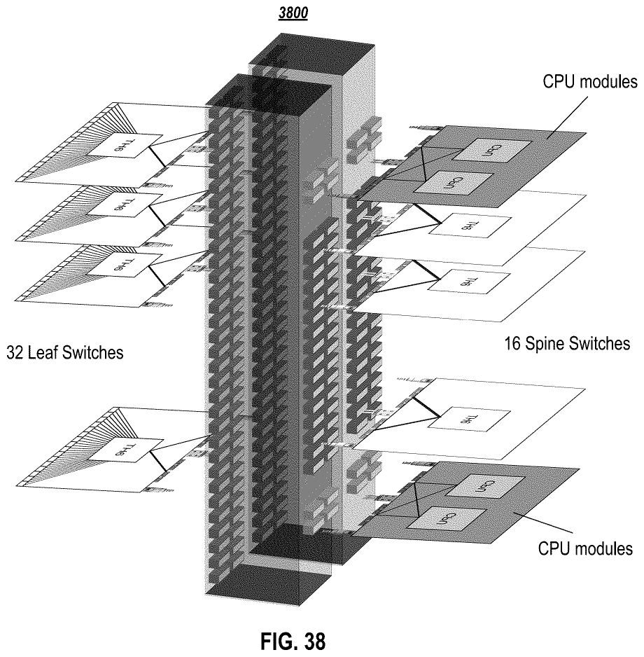

In one or more embodiments, the switches shown in FIG. 33 are autonomous (i.e., they include also a CPU (central processing unit) running an appropriate OS (operating system), such as SONIC (Software for Open Networking in the Cloud), which is an open-source network operating system (NOS) based on Linux and is overseen by the Linux Foundation. In one or more embodiments, one or more of the switches may be built without CPU and may rely on one or more centralized CPU modules. FIG. 38 depicts a rack embodiment that includes processing unit modules in addition to switching modules, according to embodiments of the present disclosure. Note that the design shown in FIG. 38 is functionally equivalent to a traditional modular switch.

### b) Embodiments of Heterogenous Module Type for One or More Faces of the Rack System

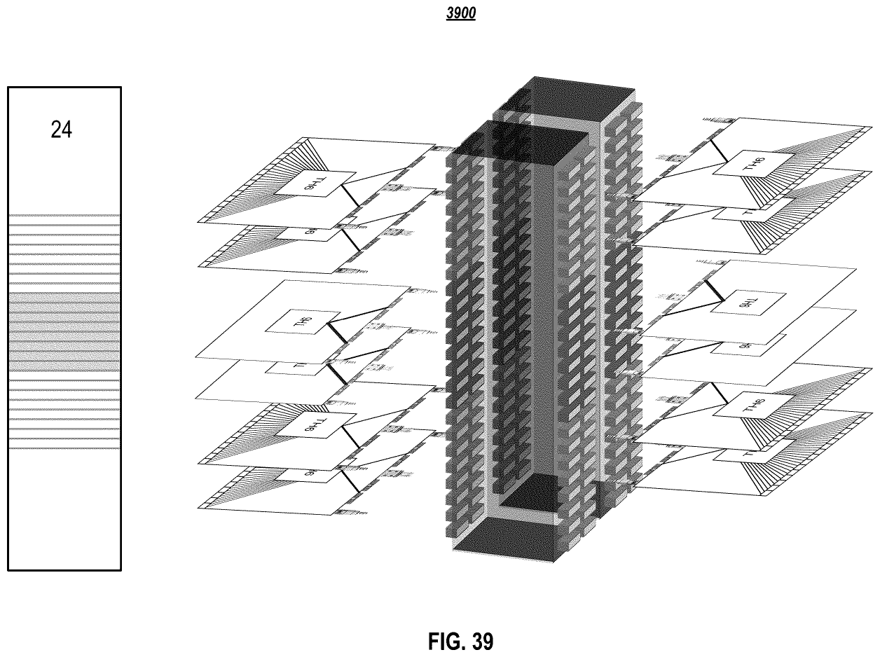

In one or more embodiments, the designs shown in FIG. 37 and FIG. 38 may be further optimized from a signal integrity perspective by the alternative embodiment shown in FIG. 39. Note that in this depicted embodiment, the configuration of modules from the first face is the same as from the second face, although it shall be noted that each face may have its own configuration. The depicted embodiment still provides 2048 800GE ports as the designs shown in FIG. 37 and FIG. 38, but it is only 24 RUs high, rather than 32 RUs high. Note that the smaller height is achieved by having these 2048 ports split between the front and the back of the rack.

One skilled in the art shall also note that by increasing the density of the switches and by decreasing distance between types of switches, the maximum distance or length from the extreme-positioned switch modules of the first type at the top or bottom of the rack to the extreme-positioned switch modules of the second type at the center of the rack may be kept below a maximum or threshold length. As the length of copper cables increases, the signal strength diminishes due to resistance, leading to signal attenuation, and signal attenuation is more pronounced at higher data rates. Also, longer copper cables are more susceptible to electromagnetic (EM) interference from external sources or even adjacent cables, which can degrade the signal quality. At the speed of interest for the typical application of such systems (e.g., 200 Gb/s), the maximum useable length of a copper cable may be between 1 and 2 meters.

While copper-based cabling has some limitations, it also has some very significant advantages. One of the primary examples is cost. Copper cables—especially relative to fiber optic cabling—are less expensive, both in terms of initial purchase and installation. Given the staggering number of cables needed for large-scale deployments, these cost differences provide significant savings. Also, copper cables are easier to install and terminate compared to fiber optic cables. Their simplicity reduces installation time and costs. Finally, copper cables are more durable and less prone to physical damage compared to fiber optic cables. They can withstand bending and pulling without significant performance degradation.

Accordingly, embodiments, like the example depicted in FIG. 39, allow for copper-based interconnect cabling systems without significant signal attenuation issues. With that said, it shall be noted that other embodiments herein that use homogenous switch type per side may also benefit from copper-based cabling due to the density provided by housing more switches per rack.

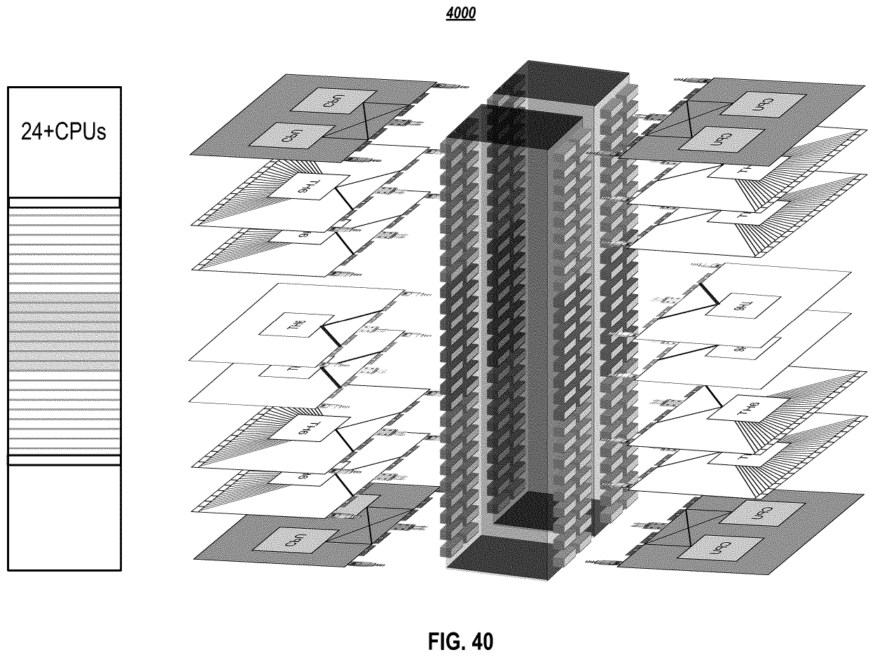

In one or more embodiments, one or more CPU modules may be added also to racks. For example, in one or more embodiments, one or more CPU modules may be added to racks with autonomous switches, in which the CPU modules operate as a platform or platforms from where a fabric manager (such as a SmartFabric Manager (SFM) by Dell Inc. of Round Rock, Texas) instance or instances may be ran. FIG. 40 depicts a rack configuration of FIG. 39 with processor modules included, according to embodiments of the present disclosure. Note that in this depicted embodiment, the configuration of modules from the first face is the same as from the second face, although it shall be noted that different configurations may exist between the two sides.

Such embodiments provide fully automated rack configurations.

### c) Installation/Configuration Method Embodiments

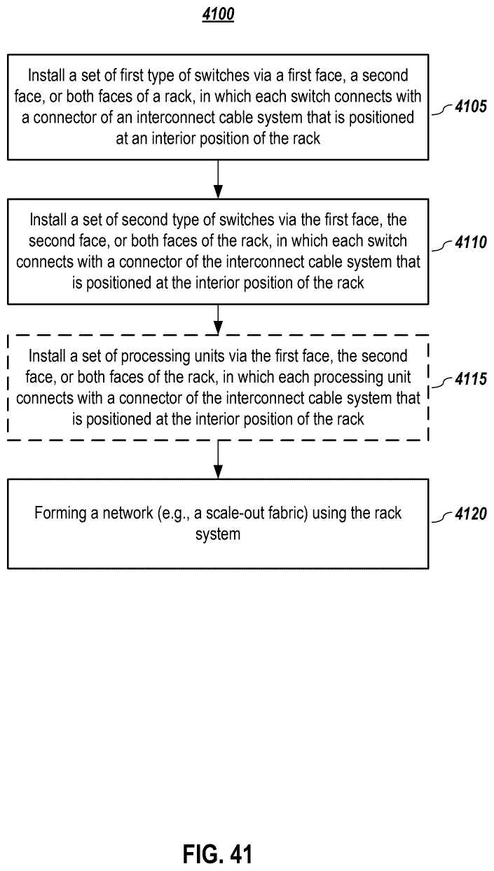

FIG. 41 depicts an example methodology for configuring/using a rack system, according to embodiments of the present disclosure. In one or more embodiments, a set of first type of switches may be installed (4105) via a first face, a second face, or both faces of a rack, in which each switch connects with a connector of an interconnect cable system that is positioned at an interior position of the rack. Similarly, in one or more embodiments, a set of second type of switches may be installed (4110) via the first face, the second face, or both faces of the rack, in which each switch connects with a connector of the interconnect cable system that is positioned at the interior position of the rack.

Optionally, in one or more embodiments, a set of processing units may be installed (4115) via the first face, the second face, or both faces of the rack, in which each processing unit connects with a connector of the interconnect cable system that is positioned at the interior position of the rack.

The populated rack system may then be used to form (4120) a network (e.g., a scale-up fabric) using the rack system. In one or more embodiments, the rack system may be combined with other rack system to form the network.

It shall be noted that, in one or more embodiments, in a rack system the interconnect cable system may comprise separate interconnect cable subsystems. For example, a rack system may employ two or more interconnect cable systems/subsystems that form (functionally, physically, or both) a single interconnect cable system for the rack.

One skilled in the art shall recognize a number of advancements and advantaged that embodiments of the present disclosure represent or provide. For example, embodiments provide new designs to interconnect many switches (e.g., leaf switches with spine switches, or spine switches with superspine switches) within a rack. Embodiments may include a rack (e.g., a modified OR v3 rack) that supports placement of cooling manifolds and power bars in the interior (e.g., the middle) of the rack and placement of passive cable cartridges in the middle of the rack to connect switches, or switches and other modules (e.g., processing modules).

In one or more embodiments, switches (e.g., leaf switches) may be built with half ports routed to the front panel and half ports routed to high-density connectors at the back of the switch, and other switches (e.g., spine switches) may be built with all ports routed to high density connectors at the back of the switch.

In one or more embodiments, switches of a first type may be connected to connectors of an interconnect cable system via a first face of the rack, and switches of a second type may be connected to connectors of an interconnect cable system via a second face of the rack. In one or more alternative embodiments, the first type of switches, the second type of switches, or both types of switches may be connected via both faces of the rack.

One skilled in the art shall recognize that the resulting rack systems provide compact, liquid cooled, and high-density switching solution (i.e., at an L11 rack level).

Examples discussed in this patent disclosure used by example the TH6 switching ASIC, Ethernet protocol, and copper interconnections within the cable cartridges of the interconnect cable system; however, it shall be noted that these are just examples and shall not be used as limiting factors for the scope of this disclosure. One skilled in the art shall recognize that aspects of the present disclosure may be applied or adapted for other use with other switching ASICs, with other protocols (e.g., InfiniBand), and with other interconnection technologies (e.g., optical cabling within the cable cartridges or a mix of optical and copper cabling).

### D. Information Handling System (IHS) Embodiments and IHS-Related Embodiments

In one or more embodiments, aspects of the present patent document may be directed to, may include, or may be implemented on one or more information handling systems (or computing systems). An information handling system/computing system may include any instrumentality or aggregate of instrumentalities operable to compute, calculate, determine, classify, process, transmit, receive, retrieve, originate, route, switch, store, display, communicate, manifest, detect, record, reproduce, handle, or utilize any form of information, intelligence, or data. For example, a computing system may be or may include a personal computer (e.g., laptop), tablet computer, mobile device (e.g., personal digital assistant (PDA), smart phone, phablet, tablet, etc.), smart watch, server (e.g., blade server or rack server), a network storage device, camera, or any other suitable device and may vary in size, shape, performance, functionality, and price. The computing system may include random access memory (RAM), one or more processing resources such as a central processing unit (CPU) or hardware or software control logic, read only memory (ROM), and/or other types of memory. Additional components of the computing system may include one or more drives (e.g., hard disk drives, solid state drive, or both), one or more network ports for communicating with external devices as well as various input and output (I/O) devices. The computing system may also include one or more buses operable to transmit communications between the various hardware components.

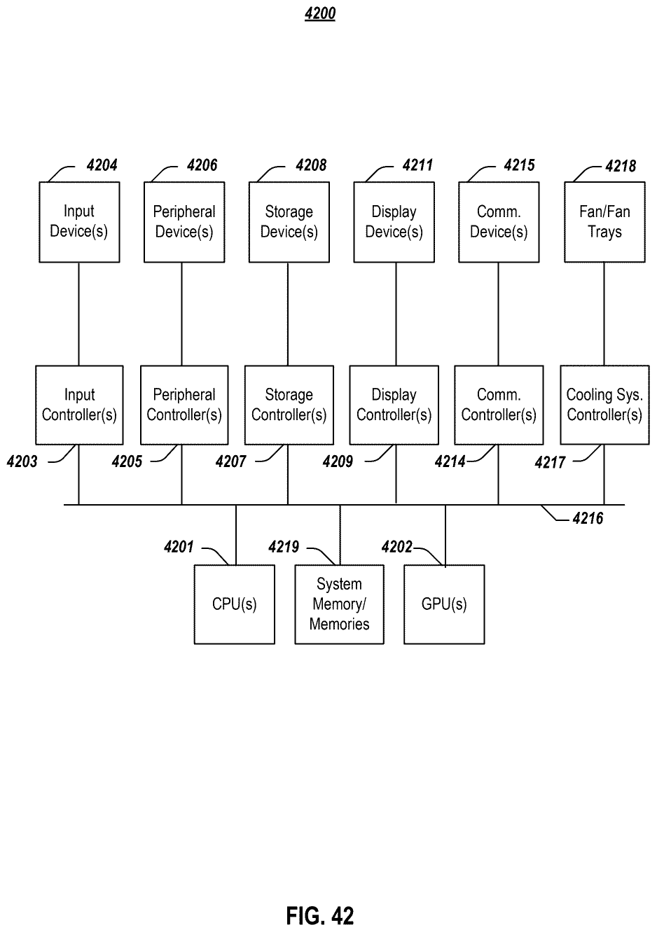

FIG. 42 depicts a simplified block diagram of an information handling system (or computing system), according to embodiments of the present disclosure. It will be understood that the functionalities shown for system 4200 may operate to support various embodiments of a computing system—although it shall be understood that a computing system may be differently configured and include different components, including having fewer or more components as depicted in FIG. 42.

As illustrated in FIG. 42, the computing system 4200 includes one or more CPUs 4201 that provides computing resources and controls the computer. CPU 4201 may be implemented with a microprocessor or the like and may also include one or more graphics processing units (GPU) 4202 and/or a floating-point coprocessor for mathematical computations. In one or more embodiments, one or more GPUs 4202 may be incorporated within the display controller 4209, such as part of a graphics card or a subcomponent. In one or more embodiments, the system may alternatively or additionally include one or more data processing units (DPUs) (not shown). In the realm of data centers and cloud computing, a DPU refers to a specialized processing unit designed to accelerate data processing tasks. DPUs are typically optimized for handling data-centric workloads such as networking, storage, security, and other tasks related to data processing and manipulation. DPUs often offload specific tasks from a main CPU, allowing for improved performance, efficiency, and scalability in data-intensive applications. They may include specialized hardware components and dedicated software to efficiently process and manage data flows within a system. The system 4200 may also include a system memory 4219, which may comprise RAM, ROM, or both.

A number of controllers and peripheral devices may also be provided, as shown in FIG. 42. An input controller 4203 represents an interface to various input device(s) 4204, such as a keyboard, mouse, touchscreen, stylus, microphone, camera, trackpad, display, etc. The computing system 4200 may also include a storage controller 4207 for interfacing with one or more storage devices 4208 each of which includes a storage medium such as magnetic tape or disk, or an optical medium that might be used to record programs of instructions for operating systems, utilities, and applications, which may include embodiments of programs that implement various aspects of the present disclosure. Storage device(s) 4208 may also be used to store processed data or data to be processed in accordance with the disclosure. The system 4200 may also include a display controller 4209 for providing an interface to a display device 4211, which may be a cathode ray tube (CRT) display, a thin film transistor (TFT) display, organic light-emitting diode, electroluminescent panel, plasma panel, or any other type of display. The computing system 4200 may also include one or more peripheral controllers or interfaces 4205 for one or more peripherals 4206. Examples of peripherals may include one or more printers, scanners, input devices, output devices, sensors, and the like. A communications controller 4214 may interface with one or more communication devices 4215, which enables the system 4200 to connect to remote devices through any of a variety of networks including the Internet, a cloud resource (e.g., an Ethernet cloud, a Fibre Channel over Ethernet (FCoE)/Data Center Bridging (DCB) cloud, etc.), a local area network (LAN), a wide area network (WAN), a storage area network (SAN) or through any suitable electromagnetic carrier signals including infrared signals. As shown in the depicted embodiment, the computing system 4200 comprises one or more fans or fan trays 4218 and a cooling subsystem controller or controllers 4217 that monitors thermal temperature(s) of the system 4200 (or components thereof) and operates the fans/fan trays 4218 to help regulate the temperature.

In the illustrated system, all major system components may connect to a bus 4216, which may represent more than one physical bus. However, various system components may or may not be in physical proximity to one another. For example, input data and/or output data may be remotely transmitted from one physical location to another. In addition, programs that implement various aspects of the disclosure may be accessed from a remote location (e.g., a server) over a network. Such data and/or programs may be conveyed through any of a variety of machine-readable media including, for example: magnetic media such as hard disks, floppy disks, and magnetic tape; optical media such as compact discs (CDs) and holographic devices; magneto-optical media; and hardware devices that are specially configured to store or to store and execute program code, such as application specific integrated circuits (ASICs), programmable logic devices (PLDs), flash memory devices, other non-volatile memory (NVM) devices (such as 3D XPoint-based devices), and ROM and RAM devices.

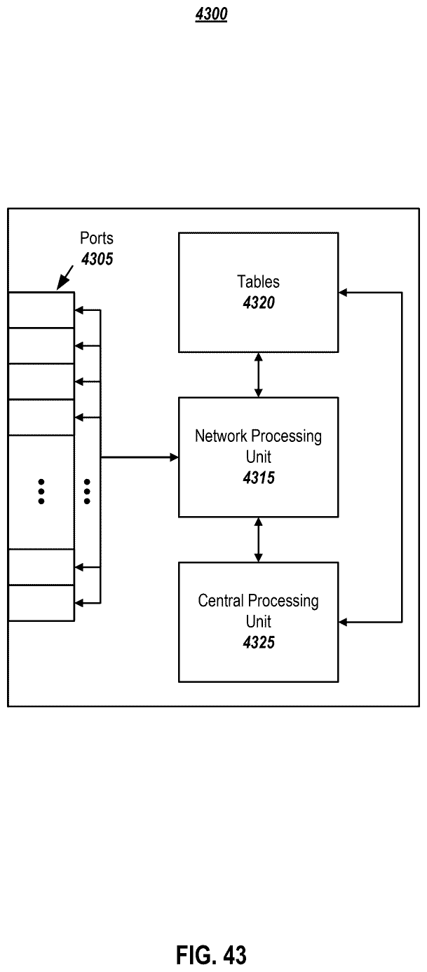

FIG. 43 depicts an alternative block diagram of an information handling system, according to embodiments of the present disclosure. It will be understood that the functionalities shown for system 4300 may operate to support various embodiments of the present disclosure although it shall be understood that such system may be differently configured and include different components, additional components, or fewer components.

The information handling system 4300 may include a plurality of I/O ports 4305, a network processing unit (NPU) 4315, one or more tables 4320, and a CPU 4325. The system includes a power supply (not shown) and may also include other components, which are not shown for sake of simplicity.

In one or more embodiments, the I/O ports 4305 may be connected via one or more cables to one or more other network devices or clients. The network processing unit 4315 may use information included in the network data received at the node 4300, as well as information stored in the tables 4320, to identify a next device for the network data, among other possible activities. In one or more embodiments, a switching fabric may then schedule the network data for propagation through the node to an egress port for transmission to the next destination.

Aspects of the present disclosure may be encoded upon one or more non-transitory computer-readable/processor-readable/information-handling-system-readable media comprising one or more sequences of instructions, which, when executed by one or more processors or processing units, causes steps to be performed. It shall be noted that the one or more non-transitory computer-readable media shall include volatile and/or non-volatile memory. It shall be noted that alternative implementations are possible, including a hardware implementation or a software/hardware implementation. Hardware-implemented functions may be realized using A SIC(s), programmable arrays, digital signal processing circuitry, or the like. Accordingly, the “means” terms in any claims are intended to cover both software and hardware implementations.

Similarly, the term “computer-readable medium or media” as used herein includes software and/or hardware having a program of instructions embodied thereon, or a combination thereof. With these implementation alternatives in mind, it is to be understood that the figures and accompanying description provide the functional information one skilled in the art would require to write program code (i.e., software) and/or to fabricate circuits (i.e., hardware) to perform the processing required.

It shall be noted that embodiments of the present disclosure may further relate to computer products with a non-transitory, tangible computer-readable medium that has computer code thereon for performing various computer-implemented operations. The media and computer code may be those specially designed and constructed for the purposes of the present disclosure, or they may be of the kind known or available to those having skill in the relevant arts. Examples of tangible computer-readable media include, for example: magnetic media such as hard disks, floppy disks, and magnetic tape; optical media such as compact discs (CDs) and holographic devices; magneto-optical media; and hardware devices that are specially configured to store or to store and execute program code, such as ASICs, PLDs, flash memory devices, other non-volatile memory devices (such as 3D XPoint-based devices), ROM, and RAM devices. Examples of computer code include machine code, such as produced by a compiler, and files containing higher level code that are executed by a computer using an interpreter. Embodiments of the present disclosure may be implemented in whole or in part as machine-executable instructions that may be in program modules that are executed by a processing device. Examples of program modules include libraries, programs, routines, objects, components, and data structures. In distributed computing environments, program modules may be physically located in settings that are local, remote, or both.

One skilled in the art shall recognize that no computing system or programming language is critical to the practice of the present disclosure. One skilled in the art will also recognize that a number of the elements described above may be physically and/or functionally separated into modules and/or sub-modules or combined together.

It will be appreciated by those skilled in the art that the preceding examples and embodiments are exemplary and not limiting to the scope of the present disclosure. It is intended that all permutations, enhancements, equivalents, combinations, and improvements thereto that are apparent to those skilled in the art upon a reading of the specification and a study of the drawings are included within the true spirit and scope of the present disclosure. It shall also be noted that elements of any claim or claims may be arranged differently including having multiple dependencies, configurations, and combinations.

What is claimed is:

1. A system comprising:
an interconnect cable system comprising:
a first face comprising interface access to:
a first set of leaf switch connectors configured to receive leaf switches housed within a rack;
a second face comprising access to:
a first set of spine switch connectors configured to receive spine switches housed within the rack; and
cable connectors that connect:
at least some of the leaf switch connectors from the first set of leaf switch connectors with one or more spine switch connectors from the first set of spine switch connectors.

2. The system of claim 1 wherein the cable connectors connect each leaf switch connector of the first set of leaf switch connectors to each of the spine switch connectors from the first set of spine switch connectors so that each leaf switch installed in its leaf switch connector can directly communicate with each spine switch.

3. The system of claim 1 wherein the cable connectors are copper-based cable connectors.

4. The system of claim 1 further comprising:
at least one set of processor connectors configured to interface with one or more sets of processor modules housed within the rack.

5. The system of claim 1 further comprising:
a second set of leaf switch connectors configured to interface with leaf switches housed within the rack; and
a second set of spine switch connectors configured to interface with spine switches housed within the rack.

6. The system of claim 5 wherein the second set of leaf switch connectors are located:
at the first face;
at the second face; or
at the first face for one or more of the second set of leaf switches connectors and at the second face for a remainder of the second set of leaf switches.

7. The system of claim 6 wherein the second set of spine switch connectors are located:
at the first face;
at the second face; or
at the first face for one or more of the second set of spine switches connectors and at the second face for a remainder of the second set of spine switches.

8. The system of claim 6 further comprising:
one or more processor connectors configured to interface with one or more sets of processor modules housed within the rack.

9. A system comprising:
an interconnect cable system for use with a rack comprising:
a first face comprising access to:
connectors configured to interface with switches of a first type;
a second face opposite the first face comprising access to:
connectors configured to interface with switches of a second type; and
cable connectors that connect at least some of the connectors from the first face with at least some of the connectors from the second face.

10. The system of claim 9 wherein the cable connectors connect each connector from the first face to each connector on the second face so that each switch installed via its connector on the first face can communicate with each switch installed via its connector on the second face.

11. The system of claim 9 wherein the cable connectors are copper-based cable connectors.

12. The system of claim 9 further comprising:
one or more processor connectors configured to interface with one or more processor modules.

13. The system of claim 9 wherein the interconnect cable system further comprises:
connectors on the first face configured to interface with switches of the second type; and
connectors on the second face configured to interface with switches of the first type.

14. The system of claim 12 further comprising:
one or more processor connectors configured to interface with one or more sets of processor modules housed within the rack.

15. A method for forming a system comprising:
given an interconnect cable system comprising:
a first face comprising access to connectors configured to interface with switches of a first type;
a second face opposed the first face comprising access to connectors configured to interface with switches of a second type; and
cable connectors that connect at least some of the connectors from the first face with at least some of the connectors from the second face,
installing switches of a first type into connectors on the first face of the interconnect cable system; and
installing switches of a second type into connectors on the second face of the interconnect cable system.

16. The method of claim 15 wherein the cable connectors are copper-based cable connectors.

17. The method of claim 15 wherein the interconnect cable system comprises:
no switch connectors for receiving switches of the second type on the first face;
no switch connectors for receiving switches of the first type on the second face; or
no switch connectors for receiving switches of the second type on the first face and no switch connectors for receiving switches of the first type on the second face.

18. The method of claim 17 wherein the interconnect cable system further comprises one or more processor connectors for receiving processor modules, and the method further comprises:
installing one or more processor modules into corresponding one or more processor connectors of the interconnect cable system.

19. The method of claim 15 wherein the first face of the interconnect cable system comprises switch connectors for receiving switches of the second type and the second face of the interconnect cable system comprises switch connectors for receiving switches of the first type, and the method further comprises:
installing one or more switches of the second type into connectors on the first face of the interconnect cable system; and
installing one or more switches of the first type into connectors on the second face of the interconnect cable system.

20. The method of claim 15 wherein the first face of the interconnect cable system, the second face of the interconnect cable system, or both comprises one or more processor connectors for receiving processor modules, and the method further comprises:
installing one or more processor modules into corresponding one or more processor connectors of the interconnect cable system.
